(19) United States
(12) Patent Application Publication
(10) Pub. No.: US 2016/0099427 A1
(43) Pub. Date: Apr. 7, 2016

(54) ORGANIC ELECTROLUMINESCENT DEVICE

(71) Applicant: SAMSUNG DISPLAY CO., LTD., Yongin-si (JP)

(72) Inventors: Hiromi Nakano, Yokohama (JP); Ikuo Sasaki, Yokohama (JP)

(21) Appl. No.: 14/836,866

(22) Filed: Aug. 26, 2015

(30) Foreign Application Priority Data
Oct. 6, 2014 (JP) 2014-205458

(51) Int. Cl. H01L 51/00; C09K 11/02

(52) U.S. Cl. CPC H01L 51/0094; C09K 11/025; H01L 51/0058; H01L 51/0061; H01L 51/0072; H01L 51/005; H01L 51/5206

(57) ABSTRACT

An organic electroluminescent device includes an anode, an emission layer, a first hole transport layer between the anode and the emission layer, the first hole transport layer including an electron accepting material, and a second hole transport layer between the anode and the emission layer, the second hole transport layer including a first hole transport material represented by the following Formula 1:

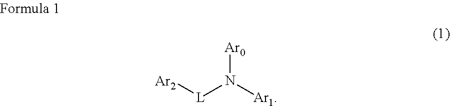

### CROSS-REFERENCE TO RELATED APPLICATION

This patent application claims priority to and the benefit of Japanese Patent Application No. 2014-205458, filed on Oct. 6, 2014, the entire content of which is hereby incorporated by reference.

### BACKGROUND

One or more aspects of embodiments of the present disclosure relate to an organic electroluminescent device.

Recently, the development of an organic electroluminescent display is being actively conducted. In addition, the development of an organic electroluminescent device which is a self-luminescent type device used in the organic electroluminescent display is also being actively conducted.

An organic electroluminescent device may have a structure including, for example, an anode, a hole transport layer on the anode, an emission layer on the hole transport layer, an electron transport layer on the emission layer, and a cathode on the electron transport layer.

In such organic electroluminescent device, holes and electrons injected from the anode and the cathode recombine in the emission layer to generate excitons, and light emission may occur when the generated excitons transition to a ground state.

However, further improvement of emission efficiency and emission life of organic electroluminescent devices is needed.

### SUMMARY

One or more aspects of embodiments of the present disclosure are directed to a novel and improved organic electroluminescent device capable of improving at least one selected from emission efficiency and emission life.

One or more embodiments of the present invention provide an organic electroluminescent device including an anode, an emission layer, a first hole transport layer between the anode and the emission layer and including an electron accepting material, and a second hole transport layer between the anode and the emission layer and including a first hole transport material represented by Formula 1:

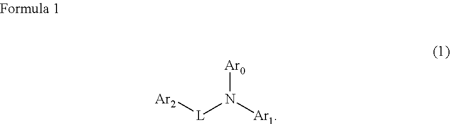

In the above Formula 1, Ar₀ and Ar₁ are each independently a substituted or unsubstituted aryl group or a substituted or unsubstituted heteroaryl group, where at least one selected from Ar₀ and Ar₁ is substituted with a substituted or unsubstituted silyl group; Ar₂ is a substituted or unsubstituted dibenzofuranyl group; and L is a bond, a substituted or unsubstituted arylene group, or a substituted or unsubstituted heteroarylene group.

According to one or more embodiments of the present invention, at least one selected from the emission efficiency and emission life of the organic electroluminescent device may be improved.

In some embodiments, the silyl group may be substituted with a substituted or unsubstituted aryl group.

When the silyl group is substituted with a substituted or unsubstituted aryl group, at least one selected from the emission efficiency and emission life of the organic electroluminescent device may be further improved.

In some embodiments, the silyl group may be substituted with an unsubstituted phenyl group.

When the silyl group is substituted with an unsubstituted phenyl group, at least one selected from the emission efficiency and emission life of the organic electroluminescent device may be further improved.

In some embodiments, L may attach to Ar₂ at position 3 of the dibenzofuranyl group (e.g., L may be attached to a carbon atom at a third position in the rings of the dibenzofuranyl group).

In this regard, at least one selected from the emission efficiency and emission life of the organic electroluminescent device may be further improved.

In some embodiments, the electron accepting material may have the lowest unoccupied molecular orbital (LUMO) level from about −9.0 eV to about −4.0 eV.

In this regard, at least one selected from the emission efficiency and emission life of the organic electroluminescent device may be improved.

In some embodiments, the emission layer may include a luminescent material having a structure represented by Formula 3:

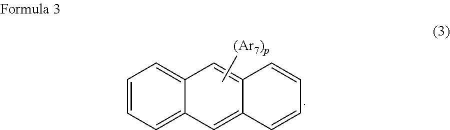

In the above Formula 3, Ar₇ is selected from hydrogen, deuterium, a substituted or unsubstituted alkyl group having 1 to 50 carbon atoms, a substituted or unsubstituted cycloalkyl group having 3 to 50 carbon atoms as ring-forming atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms as ring-forming atoms, a substituted or unsubstituted arylthio group having 6 to 50 carbon atoms as ring-forming atoms, a substituted or unsubstituted alkoxycarbonyl group having 2 to 50 carbon atoms, a substituted or unsubstituted aryl group having 6 to 50 carbon atoms as ring-forming atoms, a substituted or unsubstituted heteroaryl group having 5 to 50 carbon atoms as ring-forming atoms, a substituted or unsubstituted silyl group, a carboxyl group, a halogen atom, a cyano group, a nitro group, or a hydroxyl group; and p is an integer from 1 to 10.

When the emission layer includes the luminescent material of Formula 3, at least one selected from the emission efficiency and emission life of the organic electroluminescent device may be improved.

In some embodiments, the second hole transport layer may be positioned between the first hole transport layer and the emission layer.

In this regard, at least one selected from the emission efficiency and emission life of the organic electroluminescent device may be further improved.

In some embodiments, the second hole transport layer may be positioned adjacent to the emission layer.

In this regard, at least one selected from the emission efficiency and emission life of the organic electroluminescent device may be further improved.

In some embodiments, the first hole transport layer may be positioned adjacent to the anode.

In this regard, at least one selected from the emission efficiency and emission life of the organic electroluminescent device may be further improved.

In some embodiments, a third hole transport layer may be positioned between the first hole transport layer and the second hole transport layer and may include at least one selected from the first hole transport material and the second hole transport material.

In this regard, at least one selected from the emission efficiency and emission life of the organic electroluminescent device may be improved.

In some embodiments, the second hole transport material may have a structure represented by Formula 2:

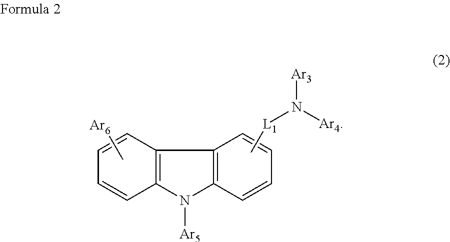

In the above Formula 2, Ar₃ to Ar₅ are each independently a substituted or unsubstituted aryl group or a substituted or unsubstituted heteroaryl group; Ar₆ is a substituted or unsubstituted aryl group, a substituted or unsubstituted heteroaryl group, a carbazolyl group or an alkyl group; and L₁ is a bond, a substituted or unsubstituted arylene group, or a substituted or unsubstituted heteroarylene group.

In this regard, at least one selected from the emission efficiency and emission life of the organic electroluminescent device may be further improved.

As described above, according to one or more embodiments of the present invention, a first hole transport layer and a second hole transport layer are positioned between an anode and an emission layer, and at least one selected from the emission efficiency and emission life of an organic electroluminescent device may be increased.

### BRIEF DESCRIPTION OF THE DRAWINGS

The accompanying drawings are included to provide a further understanding of embodiments of the present invention, and are incorporated in and constitute a part of this specification. The drawings illustrate embodiments of the present disclosure and, together with the description, serve to explain principles of the present disclosure. In the drawings:

FIG. 1 is a schematic cross-sectional view of an organic electroluminescent device according to one or more embodiments of the present invention; and

FIG. 2 is a schematic cross-sectional view of a modification of the organic electroluminescent device of FIG. 1.

### DETAILED DESCRIPTION

Embodiments of the present invention will be described below in more detail with reference to the accompanying drawings. In the specification and drawings, elements having substantially the same function will be designated by the same reference numeral, and duplicative descriptions thereof will not be provided. In addition, the expression of “a compound represented by Formula A” (where A is a number) may also refer to “Compound A”.

(1-1. Configuration of an Organic Electroluminescent Device)

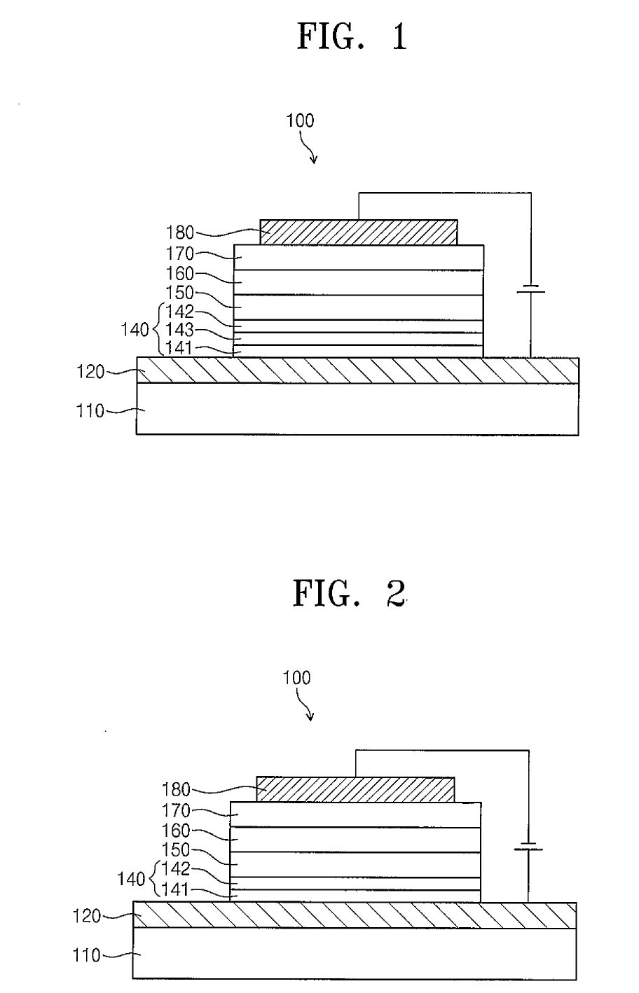

Referring to FIG. 1, the whole configuration of an organic electroluminescent device 100 according to one or more embodiments of the present invention will be explained. As shown in FIG. 1, the organic electroluminescent device 100 may include a substrate 110, a first electrode 120 positioned on the substrate 110, a hole transport layer 140 positioned on the first electrode 120, an emission layer 150 positioned on the hole transport layer 140, an electron transport layer 160 positioned on the emission layer 150, an electron injection layer 170 positioned on the electron transport layer 160, and a second electrode 180 positioned on the electron injection layer 170. The hole transport layer 140 may be formed to have a multi-layered structure composed of a plurality of layers 141, 142, and 143.

(1-2. Configuration of a Substrate)

The substrate 110 may be any suitable substrate commonly used in the art of organic electroluminescent devices. For example, the substrate 110 may be a glass substrate, a semiconductor substrate, or a transparent plastic substrate.

(1-3. Configuration of a First Electrode)

The first electrode 120 may be, for example, an anode, and may be formed on the substrate 110 using (utilizing) one or more suitable methods such as an evaporation method, a sputtering method, and/or the like. For example, the first electrode 120 may be formed as a transmission type electrode using a metal, an alloy, a conductive compound, and/or the like having large work function. In some embodiments, the first electrode 120 may be formed of indium tin oxide (ITO), indium zinc oxide (IZO), tin oxide (SnO₂), zinc oxide (ZnO), and/or the like having good transparency and conductivity. In some embodiments, the first electrode 120 may be formed as a reflection type electrode using, for example, magnesium (Mg), aluminum (Al), and/or the like.

(1-4. Configuration of a Hole Transport Layer)

The hole transport layer 140 may include any suitable hole transport material having hole transporting function. The hole transport layer 140 may be formed, for example, on the hole injection layer to a layer thickness (total layer thickness of a stacked structure) of about 10 nm to about 150 nm. In some embodiments, the hole transport layer 140 may include a first hole transport layer 141, a second hole transport layer 142, and a third hole transport layer 143. The thickness ratio of the hole transport layers is not specifically limited.

(1-4-1. Configuration of a First Hole Transport Layer)

The first hole transport layer 141 may be positioned adjacent to the first electrode 120. The first hole transport layer 141 may mainly include an electron accepting material. For example, the first hole transport layer 141 may include greater than about 50 wt % of the electron accepting material based on the total amount of the first hole transport layer 141. In some embodiments, the first hole transport layer 141 may be formed using only the electron accepting material.

The electron accepting material may be any suitable electron accepting material commonly known to those skilled in the art. In some embodiments, the electron accepting material may in one embodiment have a LUMO level from about −9.0 eV to about −4.0 eV, for example, from about −6.0 eV to about −4.0 eV. Non-limiting examples of the electron accepting material having the LUMO level from about −9.0 eV to about −4.0 eV may include compounds represented by any of Formulae 4-1 to 4-14.

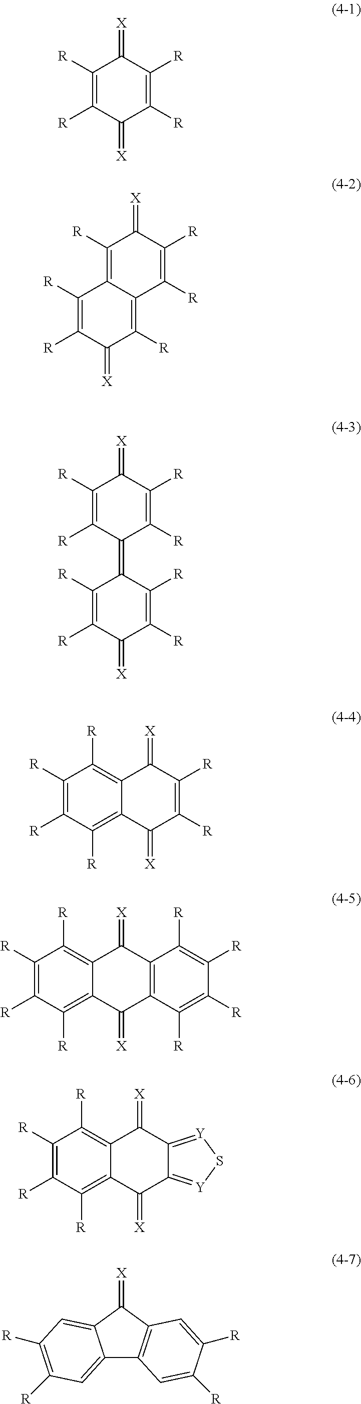

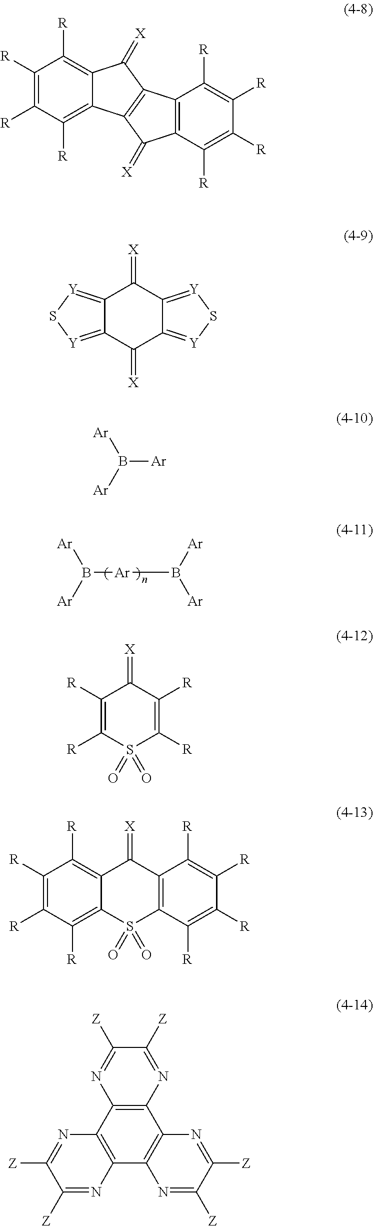

In the above Formulae 4-1 to 4-14, R may be selected from hydrogen, deuterium, halogen, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms as ring-forming atoms, or a heteroaryl group having 5 to 50 carbon atoms as ring-forming atoms; Ar may be selected from a substituted aryl group with an electron withdrawing group, an unsubstituted aryl group having 6 to 50 carbon atoms as ring-forming atoms, or a substituted or unsubstituted heteroaryl group having 5 to 50 carbon atoms as ring-forming atoms; Y may be a methine group (—CH═) or a nitrogen atom (—N═); Z may be a pseudohalogen (e.g., a pseudohalogen group) or may include sulfur (e.g., Z may be a sulfur-containing group); n may be an integer of 10 and less, and X may be one selected from the substituents represented by the following formulae X1 to X7.

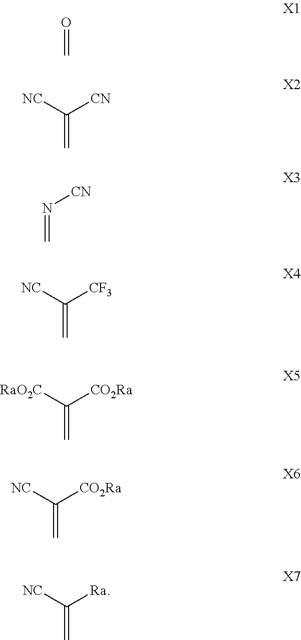

In the above Formulae X1 to X7, Ra may be selected from hydrogen, deuterium, halogen, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms as ring-forming atoms, and a substituted or unsubstituted heteroaryl group having 5 to 50 carbon atoms as ring-forming atoms.

Non-limiting examples of the substituted or unsubstituted aryl group having 6 to 50 carbon atoms as ring-forming atoms and the substituted or unsubstituted heteroaryl group having 5 to 50 carbon atoms as ring-forming atoms may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,9-phenanthroline-6-yl group, a 1,8-phenanthroline-7-yl group, a 1,8-phenanthroline-9-yl group, a 1,9-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, and/or the like.

Non-limiting examples of the substituted or unsubstituted fluoroalkyl group having 1 to 50 carbon atoms represented by R and Ra may include a perfluoroalkyl group such as a trifluoromethyl group, a pentafluoroethyl group, a heptafluoropropyl group and a heptadecafluorooctane group, a monofluoromethyl group, a difluoromethyl group, a trifluoroethyl group, a tetrafluoropropyl group, an octafluoropentyl group, and/or the like.

Non-limiting examples of the substituted or unsubstituted alkyl group having 1 to 50 carbon atoms represented by R and Ra may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-dilodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, and the like.

The substituted or unsubstituted alkoxy group having 1 to 50 carbon atoms represented by R and Ra may be a group represented by —OY. Non-limiting examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chioroethyl group, a 2-chloroethyl group, 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, and the like. Non-limiting examples of the halogen atom may include fluorine, chlorine, bromine, iodine, and the like.

Non-limiting examples of the electron accepting material may include Compounds 4-15 and 4-16 represented by Formulae 4-15 and 4-16. For example, the LUMO level of Compound 4-15 may be about −4.40 eV, and the LUMO level of Compound 4-16 may be about −5.20 eV.

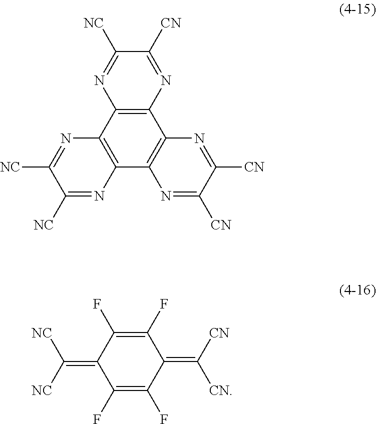 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

(1-4-2. Configuration of a Second Hole Transport Material Layer)

The second hole transport layer 142 may be positioned adjacent to the emission layer 150. The second hole transport layer 142 may include the first hole transport material represented by Formula 1:

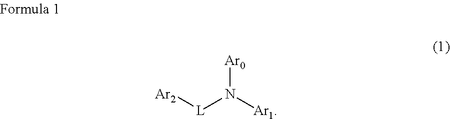

In the above Formula 1, Ar₀ and Ar₁ are each independently a substituted or unsubstituted aryl group or a substituted or unsubstituted heteroaryl group. Non-limiting examples of Ar₀ and Ar₁ may include a phenyl group, a naphthyl group, an anthracenyl group, a phenanthryl group, a biphenyl group, a terphenyl group, a fluorenyl group, a triphenylene group, a biphenylene group, a pyrenyl group, a benzothiazolyl group, a thiophenyl group, a thienothiophenyl group, a thienothienothiophenyl group, a benzothiophenyl group, a dibenzothiophenyl group, a N-arylcarbazolyl group, a N-heteroarylcarbazolyl group, a N-alkylcarbazolyl group, a phenoxazyl group, a phenothiazyl group, a pyridyl group, a pyrimidyl group, a triazile group, a quinolinyl group, a quinoxalyl group, and the like. In some embodiments, Ar₀ and Ar₁ may be a substituted or unsubstituted aryl group, for example, a substituted or unsubstituted aryl group having 6 to 18 carbon atoms as ring-forming atoms.

The substituents of Ar₀ and Ar₁ may include an alkyl group, an alkoxy group, an aryl group, a heteroaryl group, and/or the like, where the aryl group and the heteroaryl group are as described above. Non-limiting examples of the alkyl group may include a methyl group, an ethyl group, a propyl group, an isopropyl group, a cyclopropyl group, a butyl group, an isobutyl group, a t-butyl group, a cyclobutyl group, a pentyl group, an isopentyl group, a neopentyl group, a cyclopentyl group, a hexyl group, a cyclohexyl group, a heptyl group, a cycloheptyl group, an octyl group, a nonyl group, a decyl group, and the like.

Non-limiting examples of the alkoxy group may include a methoxy group, an ethoxy group, a n-propoxy group, an isopropoxy group, a n-butoxy group, an isobutoxy group, a t-butoxy group, a n-pentyloxy group, a neopentyloxy group, a n-hexyloxy group, a n-heptyloxy group, a n-octyloxy group, a 2-ethylhexyloxy group, a nonyloxy group, a decyloxy group, a 3,7-dimethyloctyloxy group, and the like.

At least one selected from Ar₀ and Ar₁ may be substituted with a substituted or unsubstituted silyl group. The substituted silyl group may include substituents selected from an alkyl group, an alkoxy group, an aryl group and a heteroaryl group, but is not limited thereto. Non-limiting examples of the substituents include those mentioned above. In some embodiments, one or more substituents of the substituted silyl group may be substituted with at least one selected from an alkyl group, an alkoxy group, an aryl group and a heteroaryl group. Non-limiting examples of the substituents include those mentioned above. In some embodiments, one or more substituents of the substituted silyl group may be a substituted or unsubstituted aryl group, for example, an unsubstituted phenyl group. In some embodiments, the silyl group may be a triphenylsilyl group.

In Formula 1, Ar₂ is a substituted or unsubstituted dibenzofuranyl group. The substituents of the substituted dibenzofuranyl group may be selected from an alkyl group, an alkoxy group, an aryl group and a heteroaryl group. Non-limiting examples of the substituents include those mentioned above. In some embodiments, one or more substituents of the substituted dibenzofuranyl group may be substituted with at least one selected from an alkyl group, an alkoxy group, an aryl group and a heteroaryl group. Non-limiting examples of the substituents include those mentioned above. The position at which the dibenzofuranyl group is coupled with L is not specifically limited. In some embodiments, L may attach to the dibenzofuranyl group at position 3 (e.g., L may be attached to a carbon atom at a third position in the rings of the dibenzofuranyl group) In this case, the properties of the organic electroluminescent device may be further improved.

L may be a bond (e.g., a direct linkage), a substituted or unsubstituted arylene group, or a substituted or unsubstituted heteroarylene group. Non-limiting examples of the arylene group and the heteroarylene group may include any of the functional groups provided as examples in connection with Ar₀ and A₁ as a divalent substituent. Non-limiting examples of the arylene group and the heteroarylene group may include a phenylene group, a naphthylene group, a biphenynylene group, a thienothiophenylene group and pyridylene group. In some embodiments, the arylene group may be an arylene group having 6 to 14 carbon atoms as ring-forming atoms, for example, a phenylene group and/or a biphenynylene group. When L is a bond, the dibenzofuranyl group and L may be directly connected (or coupled).

The first hole transport material may include at least one compound represented by any of the following Formulae 1-1 to 1-34:

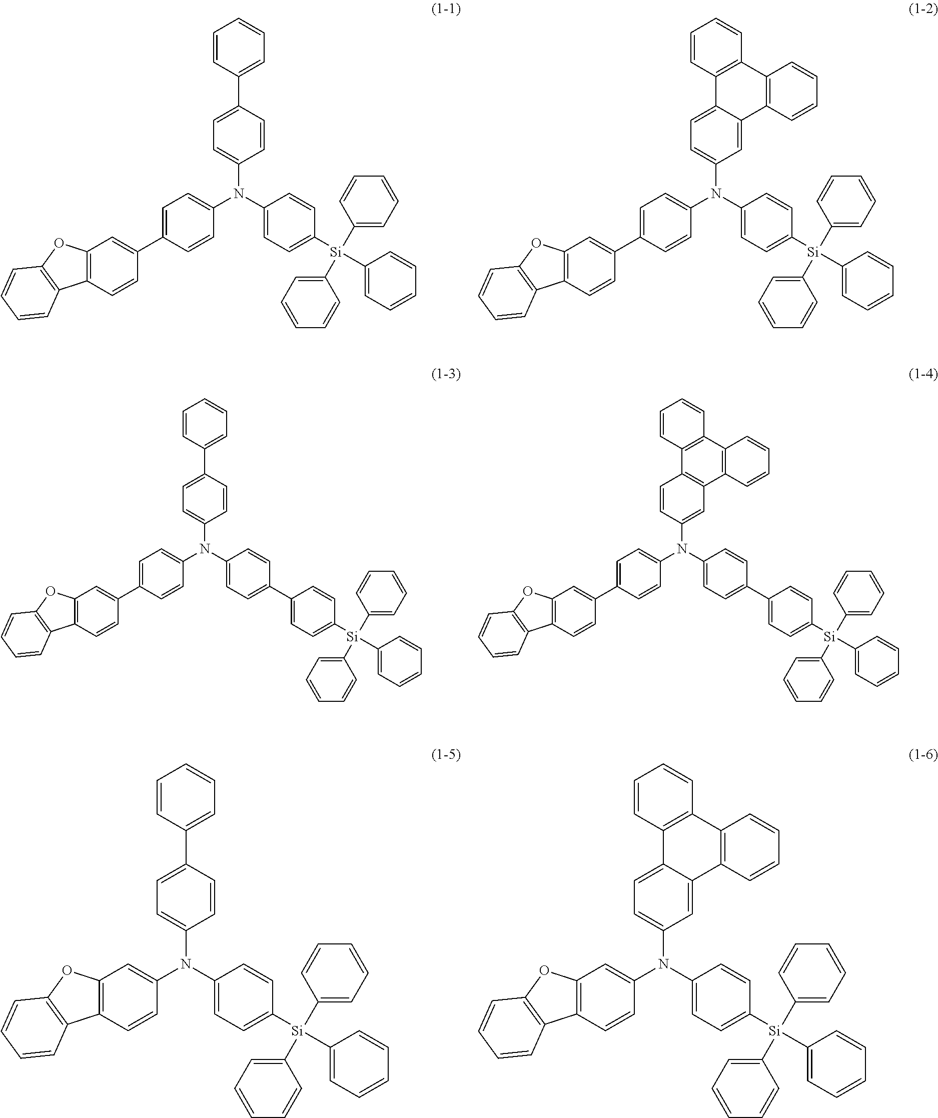

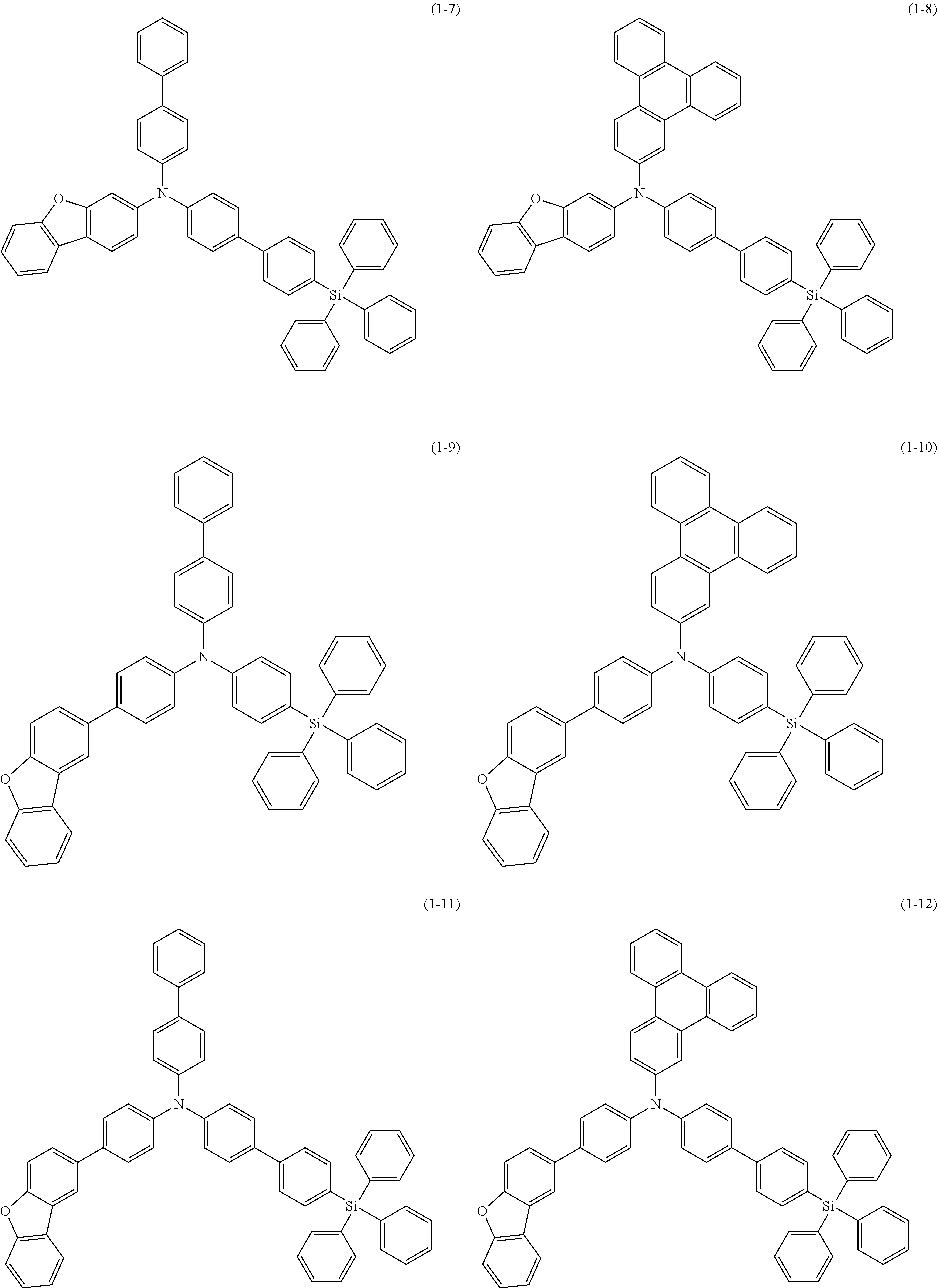

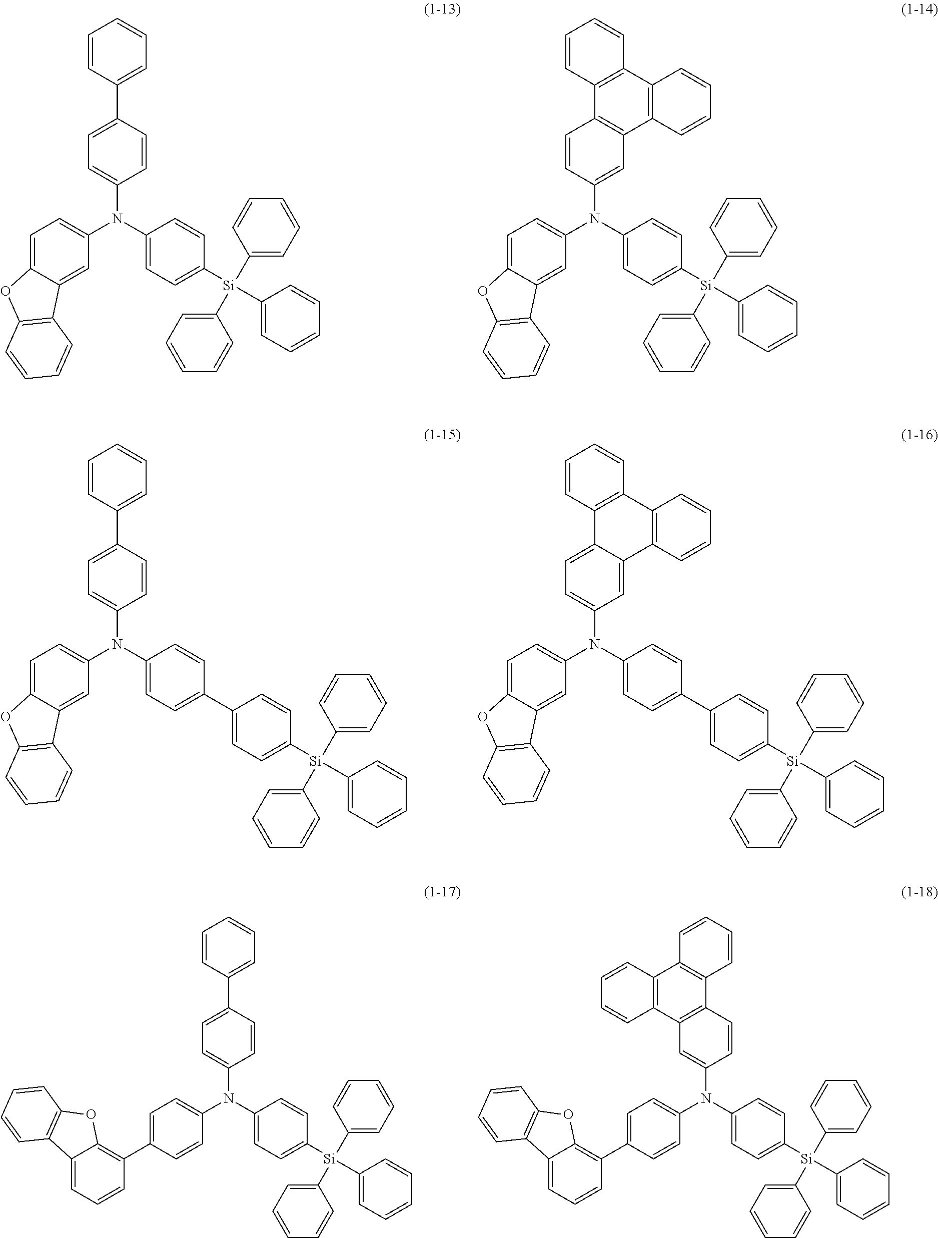

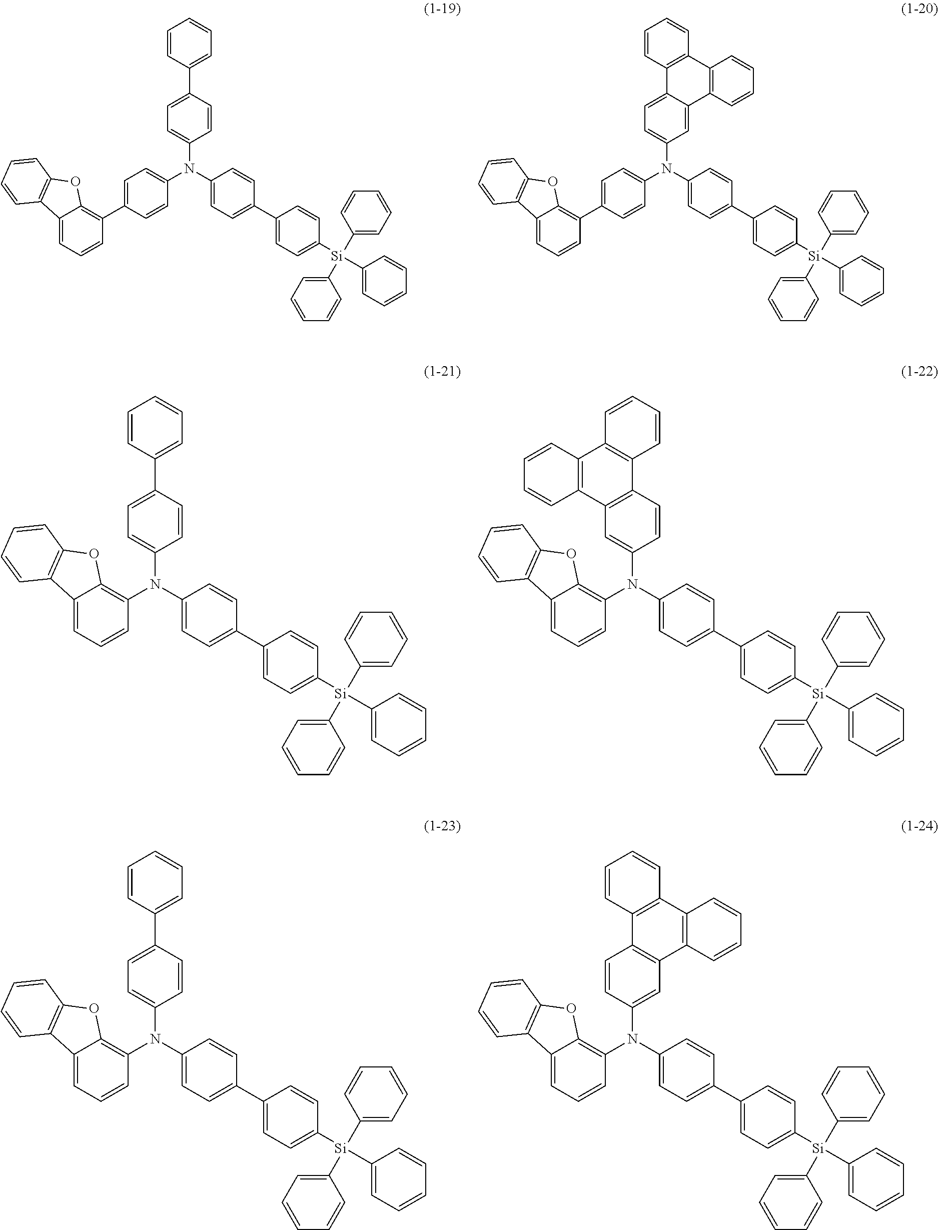

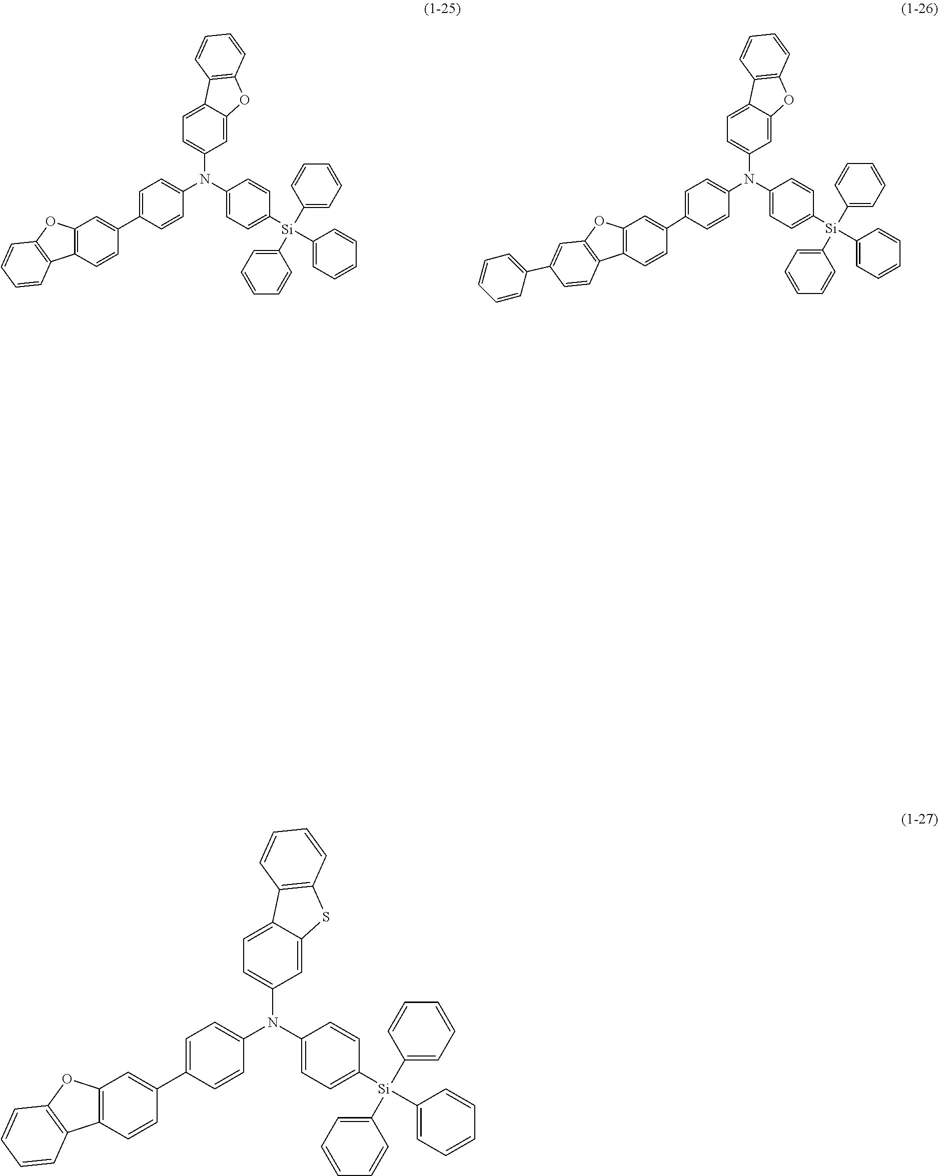 [SMILES: c1ccc([Si](c2ccccc2)(c2ccccc2)c2ccc(N(c3ccc(-c4ccc5c(c4)oc4ccccc45)cc3)c3ccc4c(c3)oc3ccccc34)cc2)cc1 ; c1ccc(-c2ccc3c(c2)oc2cc(-c4ccc(N(c5ccc([Si](c6ccccc6)(c6ccccc6)c6ccccc6)cc5)c5ccc6c(c5)oc5ccccc56)cc4)ccc23)cc1 ; c1ccc([Si](c2ccccc2)(c2ccccc2)c2ccc(N(c3ccc(-c4ccc5c(c4)oc4ccccc45)cc3)c3ccc4c(c3)sc3ccccc34)cc2)cc1]

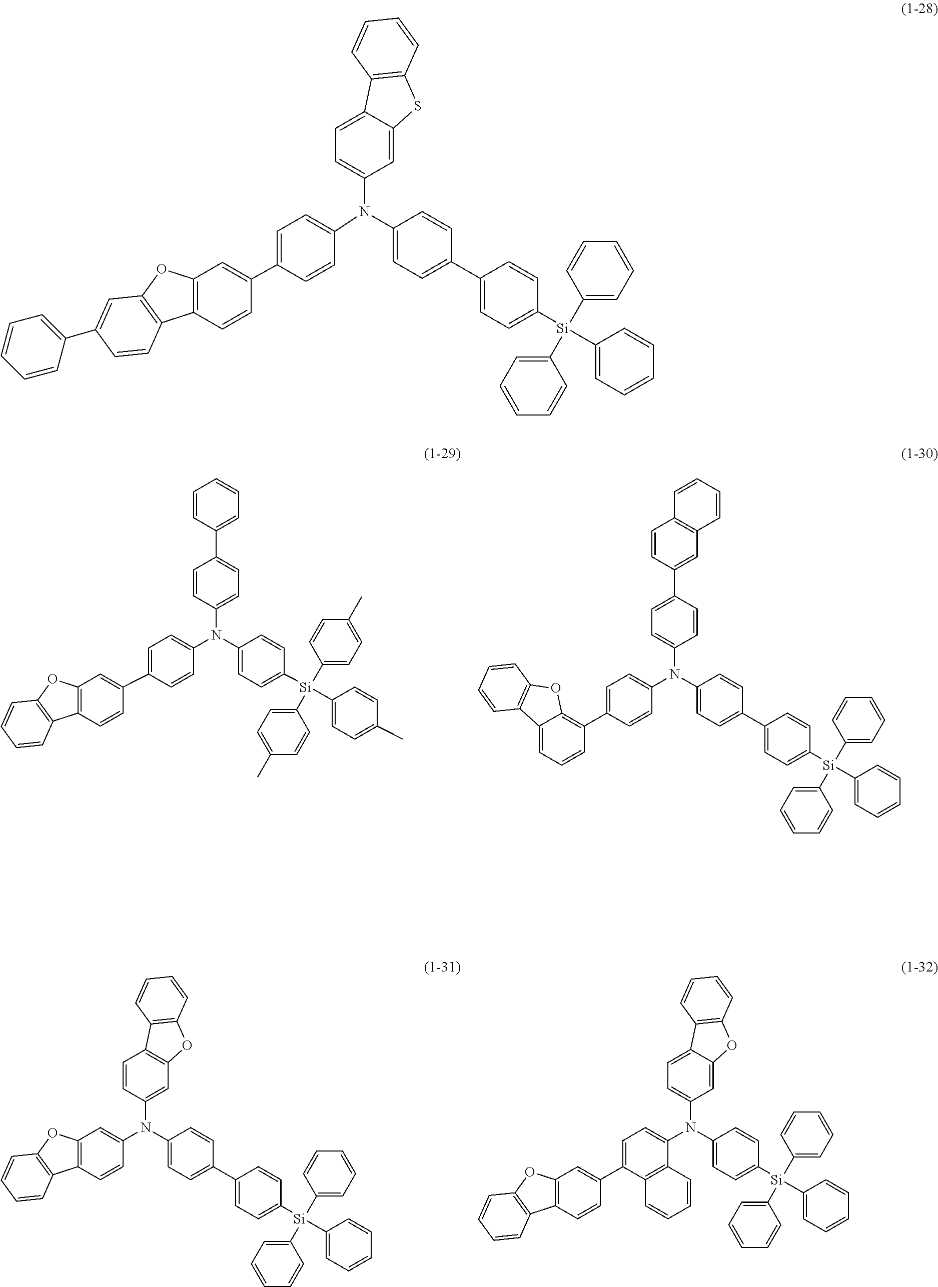

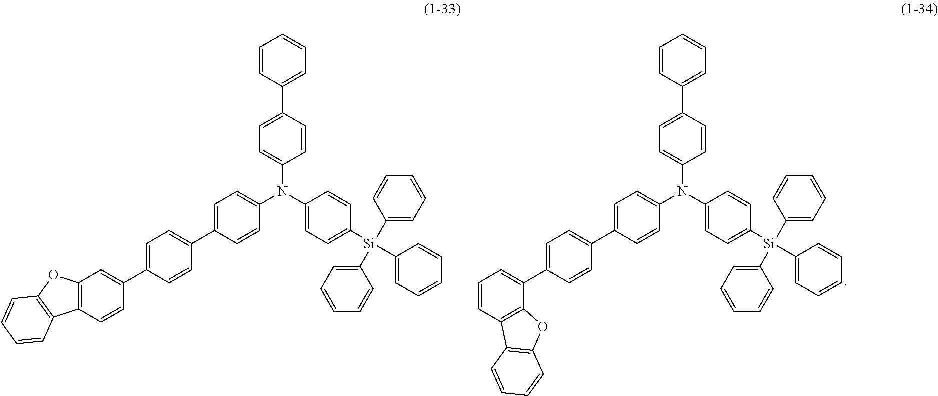 [SMILES: c1ccc(-c2ccc(N(c3ccc(-c4ccc(-c5ccc6c(c5)oc5ccccc56)cc4)cc3)c3ccc([Si](c4ccccc4)(c4ccccc4)c4ccccc4)cc3)cc2)cc1 ; c1ccc(-c2ccc(N(c3ccc(-c4ccc(-c5cccc6c5oc5ccccc56)cc4)cc3)c3ccc([Si](c4ccccc4)(c4ccccc4)c4ccccc4)cc3)cc2)cc1]

(1-4-3. Configuration of a Third Hole Transport Layer)

The third hole transport layer 143 may be positioned between the first hole transport layer 141 and the second hole transport layer 142. The third hole transport layer 143 may include at least one selected from the first hole transport material and a second hole transport material. The second hole transport material may be represented by the following Formula 2. The properties of the organic electroluminescent device 100 may be improved by using (utilizing) the compound represented by the following Formula 2 as the second hole transport material:

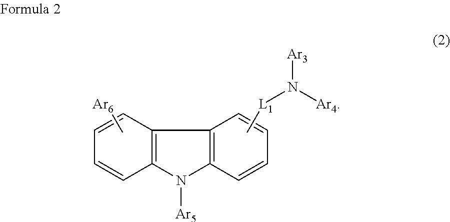

In the above Formula 2, Ar₃ to Ar₅ are each independently a substituted or unsubstituted aryl group or a substituted or unsubstituted heteroaryl group. Non-limiting examples of Ar₃ to Ar₅ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a benzoxazolyl group, a benzothiazolyl group, a quinoxalyl group, a pyrazolyl group, a dibenzofuranyl group, a dibenzothienyl group, and the like. For example, Ar₃ to Ar₅ may each independently include the phenyl group, the biphenyl group, the terphenyl group, the fluorenyl group, the dibenzofuranyl group, and/or the like.

Ar₆ may be selected from a substituted or unsubstituted aryl group, a substituted or unsubstituted heteroaryl group, a carbazolyl group, and an alkyl group. Non-limiting examples of the aryl group and the heteroaryl group are the same as those provided in connection with Ar₃ to Ar₅. For example, the aryl group may be selected from a phenyl group, a biphenyl group, a terphenyl group, a fluorenyl group, a dibenzofuranyl group, and a carbazolyl group.

L₁ may be a bond, a substituted or unsubstituted arylene group, or a substituted or unsubstituted heteroarylene group. Non-limiting examples of L₁ may include a phenylene group, a biphenylene group, a terphenylene group, a naphthylene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyrenylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienylene group, and the like. In some embodiments, L₁ may be selected from the phenylene group, the biphenylene group, the terphenylene group, the fluorenylene group, the carbazolylene group, the dibenzofuranylene group, and the like.

In some embodiments, the hole transport material represented by Formula 2 may be represented by any of the following Formulae 2-1 to 2-16:

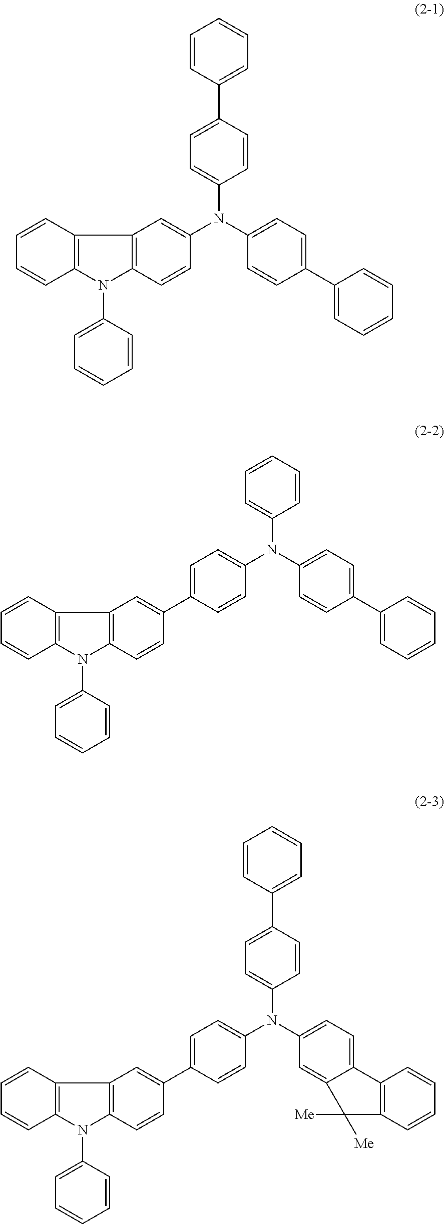 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

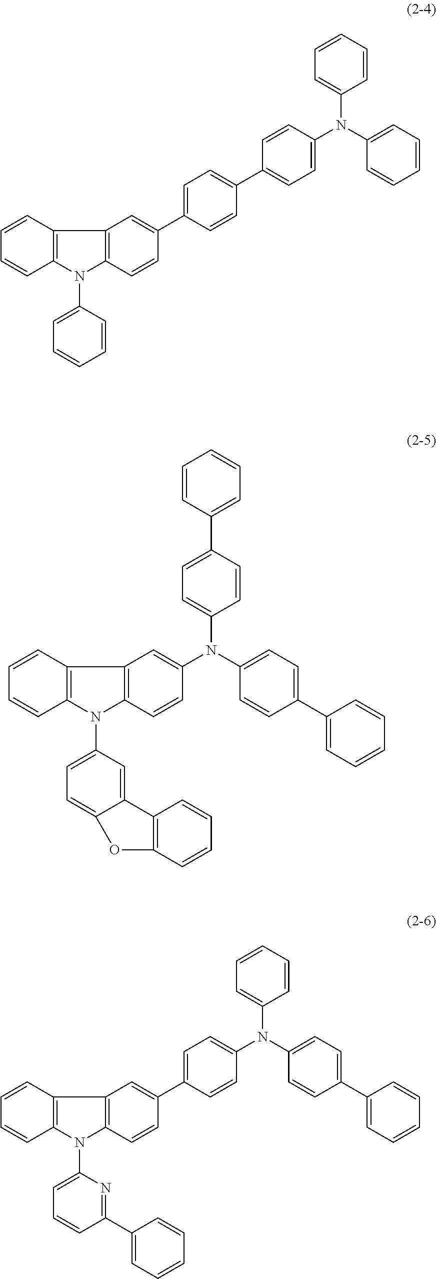 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

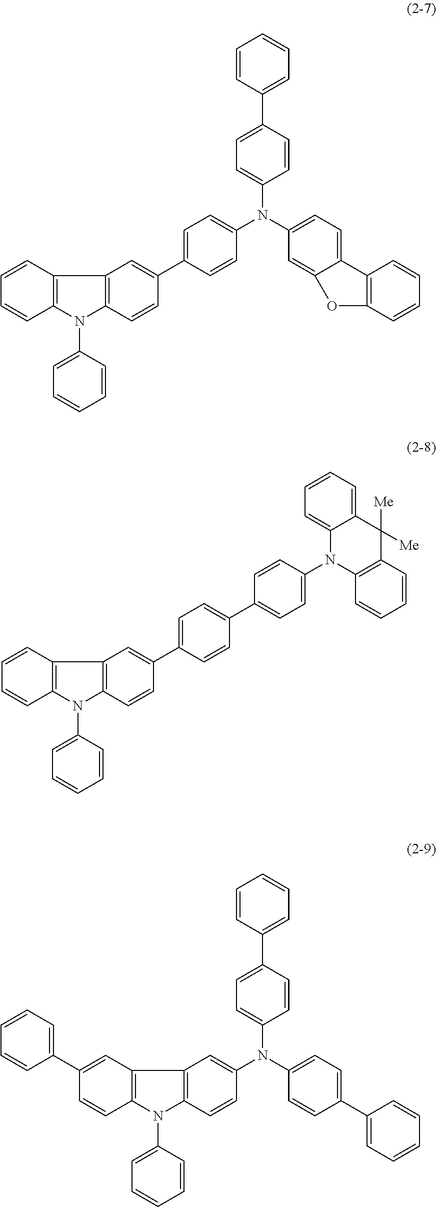 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

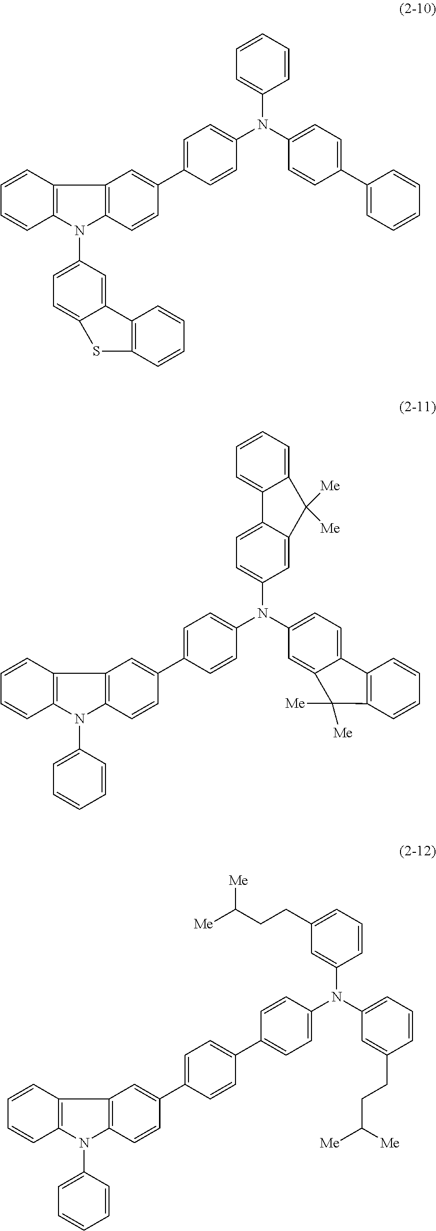 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

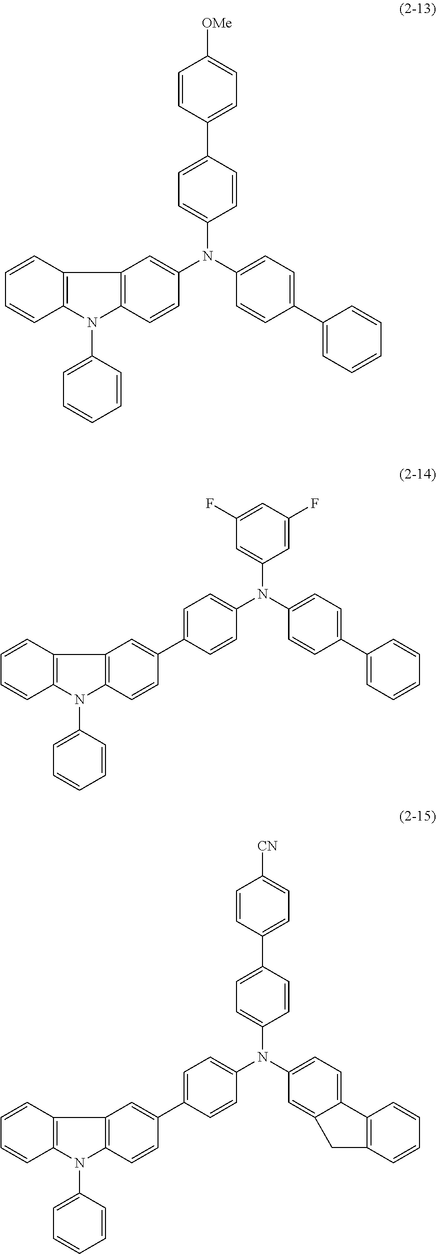 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

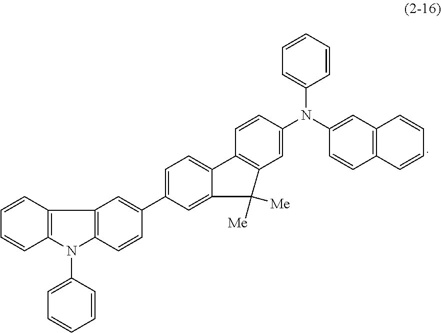 [SMILES: CC1(C)c2cc(-c3ccc4c(c3)c3ccccc3n4-c3ccccc3)ccc2-c2ccc(N(c3ccccc3)c3ccc4ccccc4c3)cc21]

However, the second hole transport material is not limited thereto and may include any suitable hole transport material other than the above-mentioned materials. For example, the second hole transport material may include 1,1-bis[(di-4-tolylamino)phenyl]cyclohexane (TAPC), a carbazole derivative such as N-phenyl carbazole, polyvinyl carbazole, and/or the like, N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), and/or the like.

(1-4-4. Example of a Hole Transport Layer According to One or More Further Embodiments of the Present Invention

As described above, the hole transport layer 140 may have a three-layer structure, but the structure of the hole transport layer 140 is not limited thereto. In other words, the hole transport layer 140 may have any suitable structure so long as the first hole transport layer 141 and the second hole transport layer 142 are positioned between the first electrode 120 and the emission layer 150. For example, as shown in FIG. 2, the third hole transport layer 143 may be omitted. In addition, the stacking order of the first hole transport layer 141 and the second hole transport layer 142 may be reversed. In some embodiments, the third hole transport layer 143 may be positioned between the first hole transport layer 141 and the first electrode 120 or between the second hole transport layer 142 and the emission layer 150. In some embodiments, the first, second, and third hole transport layers 141, 142, and 143 may be formed as a multilayer structure.

(1-5. Configuration of an Emission Layer)

The emission layer 150 is a layer emitting light via fluorescence or phosphorescence. The emission layer 150 may include a host material and a dopant material as a luminescent material. In some embodiments, the emission layer 150 may be formed to have a layer thickness from about 10 nm to about 60 nm.

The host material of the emission layer 150 may be represented by the following Formula 3:

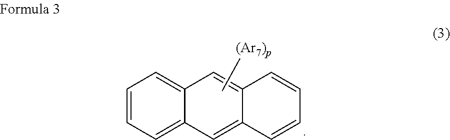

In the above Formula 3, Ar₇ is selected from hydrogen, deuterium, a substituted or unsubstituted alkyl group having 1 to 50 carbon atoms, a substituted or unsubstituted cycloalkyl group having 3 to 50 carbon atoms as ring-forming atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms as ring-forming atoms, a substituted or unsubstituted arylthio group having 6 to 50 carbon atoms as ring-forming atoms, a substituted or unsubstituted alkoxycarbonyl group having 2 to 50 carbon atoms, a substituted or unsubstituted aryl group having 6 to 50 carbon atoms as ring-forming atoms, a substituted or unsubstituted heteroaryl group having 5 to 50 carbon atoms as ring-forming atoms, a substituted or unsubstituted silyl group, a carboxyl group, halogen, a cyano group, a nitro group, and a hydroxyl group; and p is an integer from 1 to 10.

Non-limiting examples of the host material represented by Formula 3 may include compounds represented by Formulae 3-1 to 3-12:

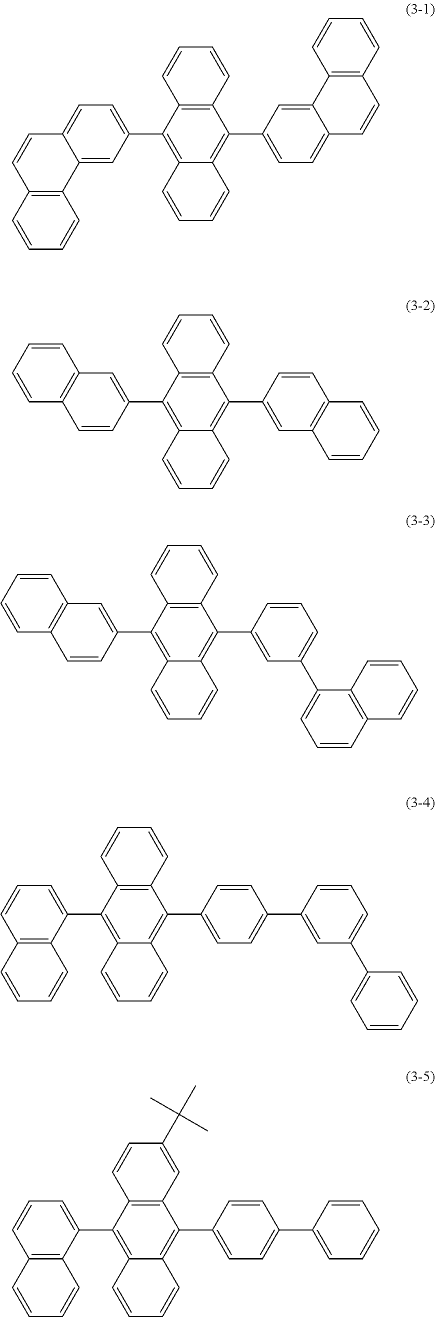

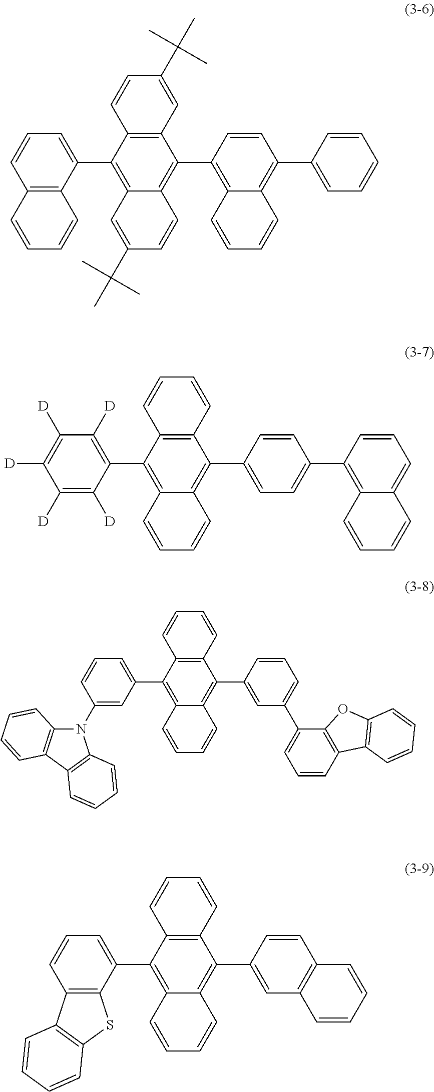

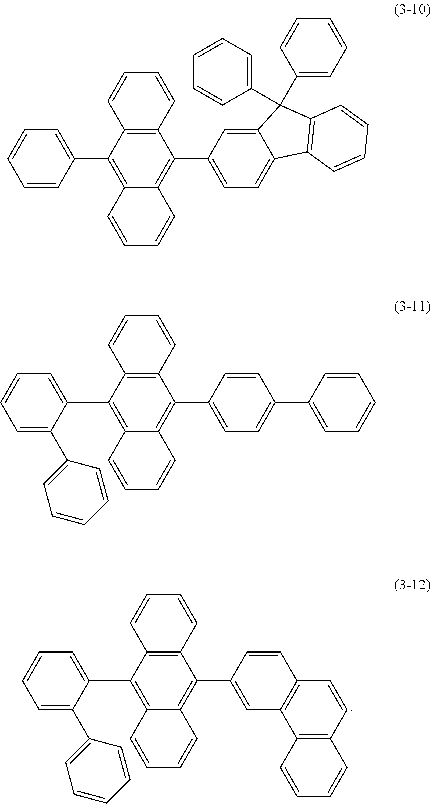

In some embodiments, the host material may further include other host materials. Examples of other host material may include tris(8-quinolinolato)aluminum (Alq3), 4,4′-N,N′-dicarbazole-biphenyl (CBP), poly(n-vinylcarbazole) (PVK), 9,10-di(naphtho-2-yl)anthracene (ADN), 4,4′,4″-tris(N-carbazolyl)triphenylamine (TCTA), 1,3,5-tris(N-phenylbenzimidazole-2-yl)benzene (TPBI), 3-tert-butyl-9,10-di(naphtho-2-yl)anthracene (TBADN), distyrylarylene (DSA), 4,4′-bis(9-carbazole)-2,2′-dimethyl-biphenyl (dmCBP), bis(2,2-diphenylvinyl)-1,1′-biphenyl (DPVBi, Formula 3-13 below), and the like. However, the host material is not limited thereto and may include any suitable material capable of being used as the host material of an organic electroluminescent device. As described above, in one embodiment, the host material may be represented by Formula 3.

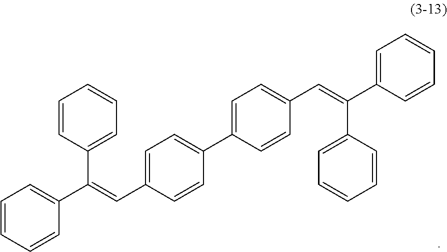 [SMILES: C(=C(c1ccccc1)c1ccccc1)c1ccc(-c2ccc(C=C(c3ccccc3)c3ccccc3)cc2)cc1]

In some embodiments, the emission layer 150 may be formed to emit light of specific color. For example, the emission layer 150 may be formed as a red emitting layer, a green emitting layer, or a blue emitting layer.

In the case that the emission layer 150 is the blue emitting layer, any suitable blue dopant may be used. For example, the blue dopant may include perylene and/or derivatives thereof, an iridium (Ir) complex such as bis[2-(4,6-difluorophenyl)pyridinate]picolinate iridium(III) (Flrpic), and/or the like, but is not limited thereto.

In the case that the emission layer 150 is the red emitting layer, any suitable red dopant may be used. For example, the red dopant may include rubrene and/or derivatives thereof, 4-dicyanomethylene-2-(p-dimethylaminostyryl)-6-methyl-4H-pyrane (DCM) and/or derivatives thereof, an iridium complex such as bis(1-phenylisoquinoline)(acetylacetonate) iridium(III) (Ir(piq)₂(acac), an osmium (Os) complex, a platinum complex, and/or the like, but is not limited thereto.

In the case that the emission layer 150 is the green emitting layer, any suitable green dopant may be used. For example, the green dopant may include coumarin and/or derivatives thereof, an iridium complex such as tris(2-phenylpyridine) iridium(III) (Ir(ppy)₃), and/or the like, but is not limited thereto.

The electron transport layer 160 is a layer including an electron transport material and having electron transporting function. The electron transport layer 160 may be formed, for example, on the emission layer 150 to a layer thickness from about 15 nm to about 50 nm. The electron transport layer 160 may be formed using any suitable electron transport material including, without limitation, a quinoline derivative such as tris(8-quinolinolato)aluminum (Alq3), a 1,2,4-triazole derivative (TAZ), bis(2-methyl-8-quinolinolato)-(p-phenylphenolate)-aluminum (BAIq), berylliumbis(benzoquinoline-10-olate) (BeBq2), a Li complex such as lithium quinolate (LiQ), and/or the like.

The electron injection layer 170 is a layer that facilitates the injection of electrons from the second electrode 180 and may be formed, for example, on the electron transport layer 160 to a layer thickness from about 0.3 nm to about 9 nm. The electron injection layer 170 may be formed using any suitable material that is commonly used in the art as a material for forming an electron injection layer including, without limitation, lithium fluoride (LiF), sodium chloride (NaCl), cesium fluoride (CsF), lithium oxide (Li₂O), barium oxide (BaO), and/or the like.

The second electrode 180 may be, for example, a cathode. In some embodiments, the second electrode 180 may be formed as a reflection type electrode using a metal, an alloy, a conductive compound, and/or the like having small work function. Non-limiting examples of the material for forming the second electrode 180 may include lithium (Li), magnesium (Mg), aluminum (Al), aluminum-lithium (Al—Li), calcium (Ca), magnesium-indium (Mg—In), magnesium-silver (Mg—Ag), and/or the like. In addition, the second electrode 180 may be formed as a transmission type electrode using ITO, IZO, and/or the like. The second electrode 180 may be formed on the electron injection layer 170 using, for example, an evaporation method and/or a sputtering method.

(1-6. Example of an Organic Electroluminescent Device According to One or More Further Embodiments of the Present Invention)

In the embodiment of FIG. 1, the layers of the organic electroluminescent device other than the hole transport layer 140 have a single layer structure. However, one or more of the layers may have a multilayer structure. In addition, in the organic electroluminescent device 100 illustrated in FIG. 1, a hole injection layer may be positioned between the hole transport layer 140 and the first electrode 120.

The hole injection layer is a layer that facilitates the injection of holes from the first electrode 120 and may be formed, for example, on the first electrode 120 to a layer thickness from about 10 nm to about 150 nm. Any suitable hole injection material may be utilized for forming the hole injection layer. Non-limiting examples of the hole injection material may include a triphenylamine-containing polyether ketone (TPAPEK), 4-isopropyl-4′-methyldiphenyliodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), a phthalocyanine compound (such as copper phthalocyanine, and/or the like), 4,4′,4″-tris(3-methylphenylphenylamino)triphenylamine (m-MTDATA), N,N′-di(1-naphthyl)-N,N′-diphenylbenzidine (NPB), 4,4′,4″-tris{N,N-diphenylamino}triphenylamine (TDATA), 4,4′,4″-tris(N,N-2-naphthylphenylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA) or polyaniline/poly(4-styrenesulfonate (PANI/PSS), and the like.

In some embodiments, in the organic electroluminescent device 100, at least one selected from the electron transport layer 160 and the electron injection layer 170 may be omitted.

### EXAMPLES

Hereinafter, an organic electroluminescent device according to one or more embodiments of the present disclosure will be explained in more detail by referring to examples and comparative examples. However, as those skilled in the art would recognize, the following embodiments are provided for illustrative purposes only and are not intended to limit the scope of the present invention.

### Synthetic Example 1

### Synthesis of Compound 1-3 Represented by Formula 1-3

According to the following reaction scheme, Compound 1-3 represented by Formula 1-3 was synthesized.

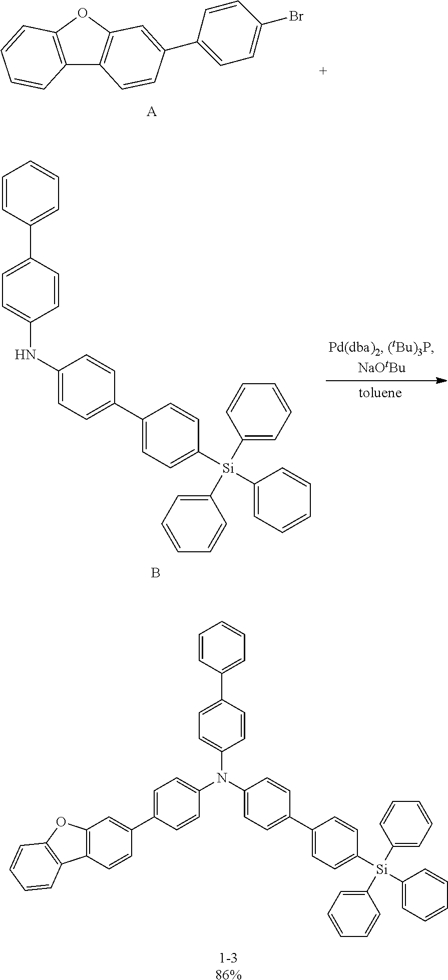

In the synthesis of Compound 1-3, 1.50 g of Compound A, 1.90 g of Compound B, 0.11 g of bis(dibenzylideneacetone)palladium(0) (Pd(dba)₂), 0.15 g of tri-tert-butylphosphine ((t-Bu)₃P) and 0.54 g of sodium tert-butoxide were added to a 100 mL three necked flask under an argon atmosphere, followed by heating and refluxing the resulting mixture in 45 mL of a toluene solvent for about 6 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 1.86 g of a target product as a white solid (Yield 86%).

The chemical shift values of the target product measured by ¹H NMR were 8.000 (d, 1H), 7.96 (d, 1H), 7.78 (d, 1H), 7.64-7.53 (m, 20H), 7.48-7.33 (m, 14H), 7.29-7.25 (m, 6H). In addition, the molecular weight of the target product measured by FAB-MS was about 822. From these results, the target product was confirmed to be Compound 1-3.

### Synthetic Example 2

### Synthesis of Compound 1-9 Represented by Formula 1-9

According to the following reaction scheme, Compound 1-9 represented by Formula 1-9 was synthesized.

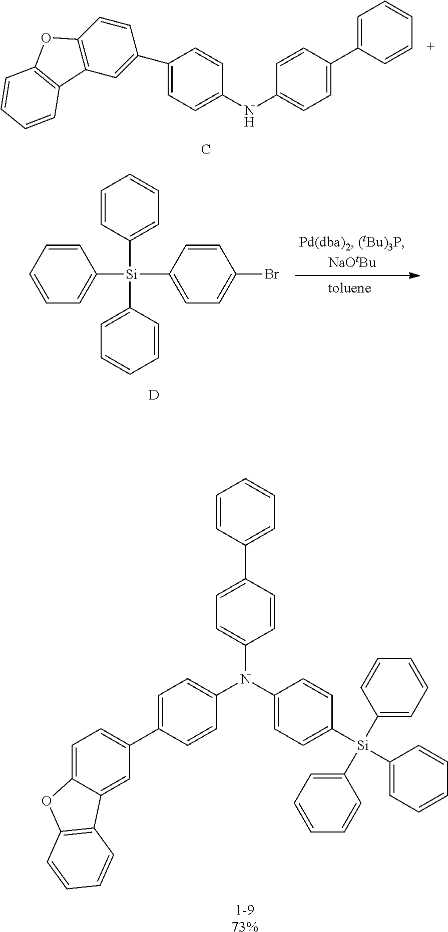

In the synthesis of Compound 1-9, 2.50 g of Compound C, 2.52 g of Compound D, 0.25 g of bis(dibenzylideneacetone)palladium(0) (Pd(dba)₂), 0.10 g of tri-tert-butylphosphine ((t-Bu)₃P) and 1.85 g of sodium tert-butoxide were added to a 100 mL three necked flask under an argon atmosphere, followed by heating and refluxing the resulting mixture in 60 mL of a toluene solvent for about 8 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 3.31 g of a target product as a white solid (Yield 73%).

The chemical shift values of the target product measured by ¹H NMR were 8.13 (d, 1H), 7.98 (d, 1H), 7.69-7.24 (m, 35H), 7.16 (d, 2H). In addition, the molecular weight of the target product measured by FAB-MS was about 745. From these results, the target product was confirmed to be Compound 1-9.

### Synthetic Example 3

### Synthesis of Compound 1-17 Represented by Formula 1-17

According to the following reaction scheme, Compound 1-17 represented by Formula 1-17 was synthesized.

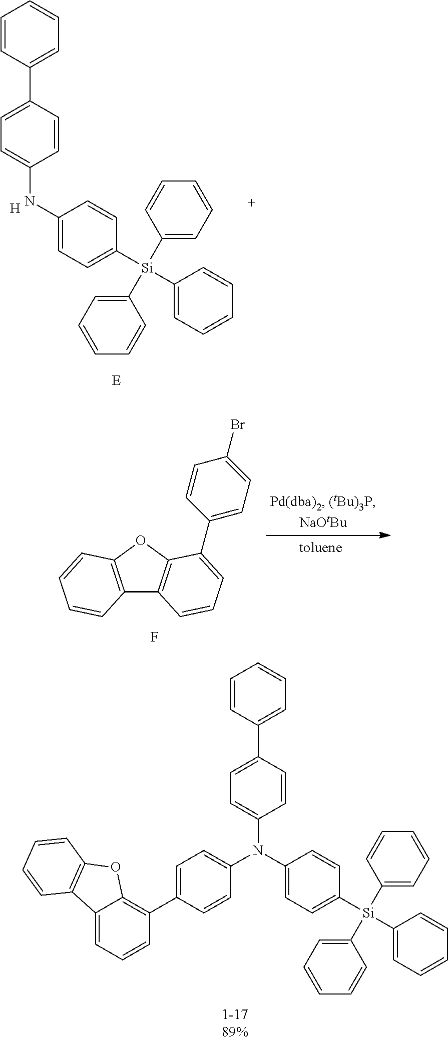

In the synthesis of Compound 1-17, 0.8 g of Compound E, 0.54 g of Compound F, 0.06 g of bis(dibenzylideneacetone)palladium(0) (Pd(dba)₂), 0.12 g of tri-tert-butylphosphine ((t-Bu)₃P) and 0.3 g of sodium tert-butoxide were added to a 100 mL three necked flask under an argon atmosphere, followed by heating and refluxing the resulting mixture in 30 mL of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 0.95 g of a target product as a white solid (Yield 89%).

The chemical shift values of the target product measured by ¹H NMR were 7.99 (d, 1H), 7.91 (d, 1H), 7.87 (d, 2H), 7.62-7.28 (m, 33H), 7.20 (d, 2H). In addition, the molecular weight of the target product measured by FAB-MS was about 745. From these results, the target product was confirmed to be Compound 1-17.

### Synthetic Example 4

### Synthesis of Compound 1-19 Represented by Formula 1-19

According to the following reaction scheme, Compound 1-19 represented by Formula 1-19 was synthesized.

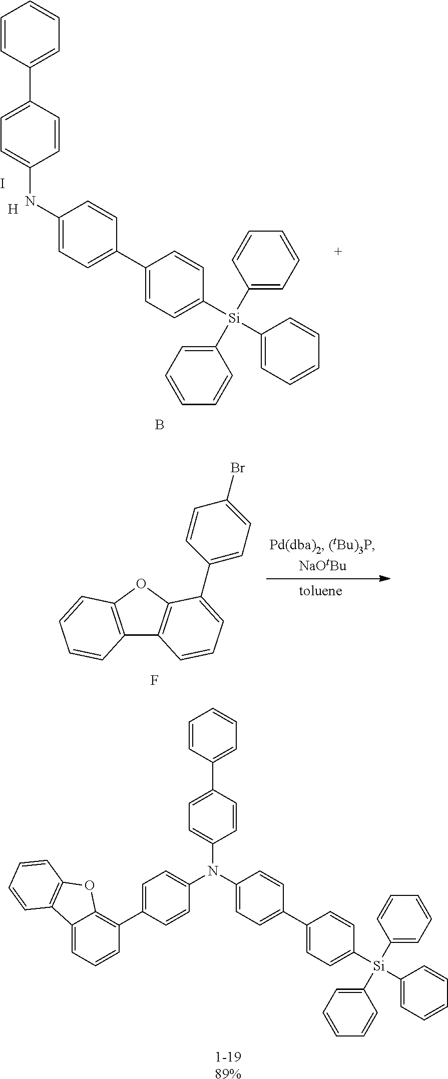

In the synthesis of Compound 1-19, 1.50 g of Compound B, 0.87 g of Compound F, 0.11 g of bis(dibenzylideneacetone)palladium(O) (Pd(dba)₂), 0.15 g of tri-tert-butylphosphine ((t-Bu)₃P) and 0.54 g of sodium tert-butoxide were added to a 100 mL three necked flask under an argon atmosphere, followed by heating and refluxing the resulting mixture in 45 mL of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 1.86 g of a target product as a white solid (Yield 89%).

The chemical shift values of the target product measured by ¹H NMR were 8.000 (d, 1H), 7.93-7.87 (m, 3H), 7.66-7.53 (m, 17H), 7.50-7.28 (m, 22H). In addition, the molecular weight of the target product measured by FAB-MS was about 822. From these results, the target product was confirmed to be Compound 1-19.

### Synthetic Example 5

### Synthesis of Compound 1-25 Represented by Formula 1-25

According to the following reaction scheme, Compound 1-25 represented by Formula 1-25 was synthesized.

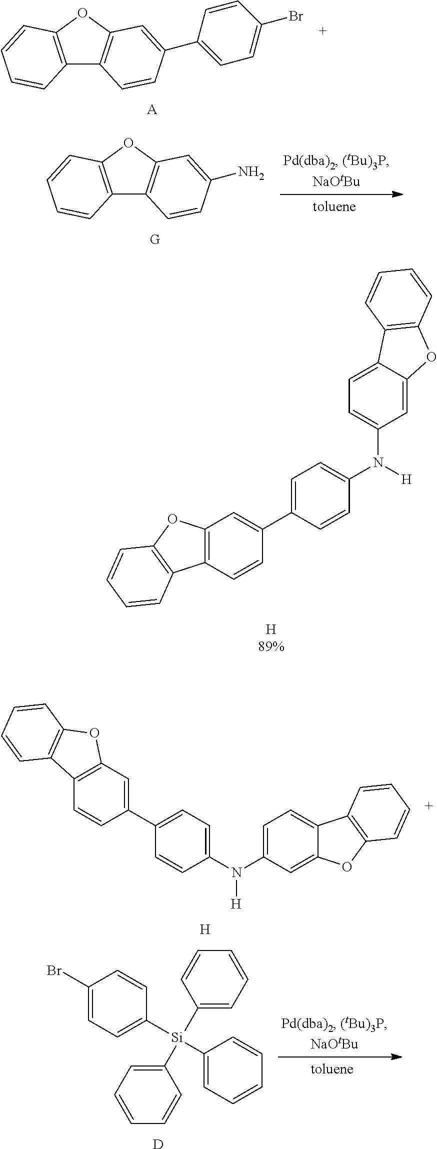

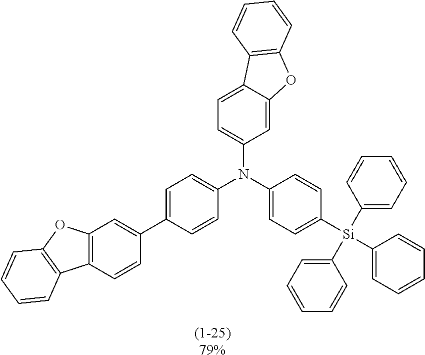 [SMILES: c1ccc([Si](c2ccccc2)(c2ccccc2)c2ccc(N(c3ccc(-c4ccc5c(c4)oc4ccccc45)cc3)c3ccc4c(c3)oc3ccccc34)cc2)cc1 ; "(1-25)79%"]

In the synthesis of Compound 1-25, 3.00 g of Compound A, 1.68 g of Compound G, 0.20 g of bis(dibenzylideneacetone)palladium(0) (Pd(dba)₂), 0.25 g of tri-tert-butyiphosphine ((t-Bu)₃P) and 0.78 g of sodium tert-butoxide were added to a 100 mL three necked flask under an argon atmosphere, followed by heating and refluxing the resulting mixture in 80 mL of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 3.52 g of a target product as a white solid (Yield 89%).

The chemical shift values of the target product measured by ¹H NMR were 8.36 (s, 1H), 8.003 (s, 2H), 7.98-7.76 (m, 5H), 7.55-7.37 (m, 8H), 7.31-7.29 (m, 2H), 6.91 (d, 1H). In addition, the molecular weight of the target product measured by FAB-MS was about 425. From these results, the target product was confirmed to be Compound H.

Then, 3.52 g of Compound H, 3.44 g of Compound D, 0.25 g of bis(dibenzylideneacetone)palladium(0) (Pd(dba)₂), 0.28 g of tri-tert-butylphosphine ((t-Bu)₃P) and 1.90 g of sodium tert-butoxide were added to a 100 mL three necked flask under an argon atmosphere, followed by heating and refluxing the resulting mixture in 80 mL of a toluene solvent for about 7 hours. After air cooling the obtained mixture, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 4.97 g of a target product as a white solid (Yield 79%).

The chemical shift values of the target product measured by ¹H NMR were 8.003-7.97 (m, 2H), 7.98-7.76 (m, 5H), 7.55-7.31 (m, 29H), 6.91 (d, 1H). In addition, the molecular weight of the target product measured by FAB-MS was about 760. From these results, the target product was confirmed to be Compound 1-25.

### Synthetic Example 6

### Synthesis of Compound 1-28 Represented by Formula 1-28

According to the following reaction scheme, Compound 1-28 represented by Formula 1-28 was synthesized.

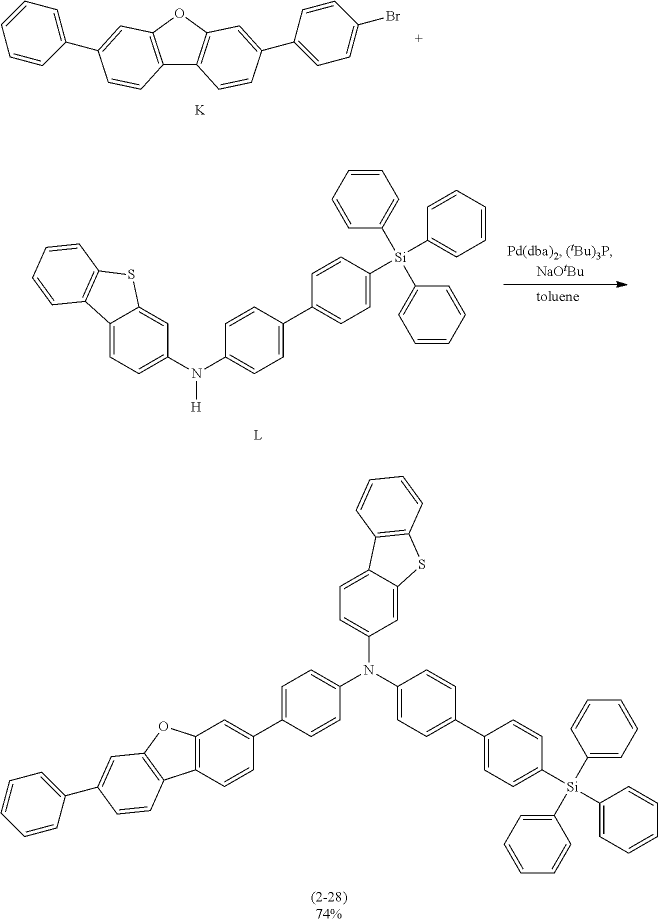

In the synthesis of Compound 1-28, 1.50 g of Compound K, 2.55 g of Compound L, 0.20 g of bis(dibenzylideneacetone)palladium(0) (Pd(dba)₂), 0.30 g of tri-tert-butylphosphine ((t-Bu)₃P) and 0.76 g of sodium tert-butoxide were added to a 100 mL three necked flask under an argon atmosphere, followed by heating and refluxing the resulting mixture in 80 mL of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 2.5 g of a target product as a white solid (Yield 74%).

The chemical shift values of the target product measured by ¹H NMR were 8.45 (d, 1H), 8.004-8.000 (m, 3H), 7.93-7.75 (m, 9H), 7.64-7.46 (m, 3H), 7.56-7.38 (m, 29H). In addition, the molecular weight of the target product measured by FAB-MS was about 928. From these results, the target product was confirmed to be Compound 1-28.

### Synthetic Example 7

### Synthesis of Compound 1-29 Represented by Formula 1-29

According to the following reaction scheme, Compound 1-29 represented by Formula 1-29 was synthesized.

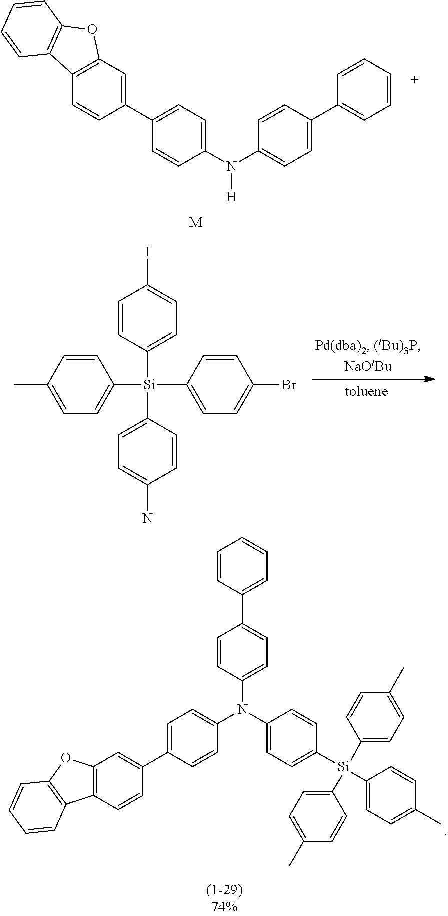

In the synthesis of Compound 1-29, 1.50 g of Compound M, 1.99 g of Compound N, 0.18 g of bis(dibenzylideneacetone)palladium(0) (Pd(dba)₂), 0.32 g of tri-tert-butylphosphine ((t-Bu)₃P) and 0.77 g of sodium tert-butoxide were added to a 100 mL three necked flask under an argon atmosphere, followed by heating and refluxing the resulting mixture in 80 ml of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 2.5 g of a target product as a white solid (Yield 74%).

The chemical shift values of the target product measured by ¹H NMR were 8.003-7.97 (m, 2H), 7.82 (d, 1H), 7.76-7.75 (m, 3H), 7.55-7.26 (m, 30H), 2.37 (s, 9H). In addition, the molecular weight of the target product measured by FAB-MS was about 788. From these results, the target product was confirmed to be Compound 1-29.

### Synthetic Example 8

### Synthesis of Compound 1-31 Represented by Formula 1-31

According to the following reaction scheme, Compound 1-31 represented by Formula 1-31 was synthesized.

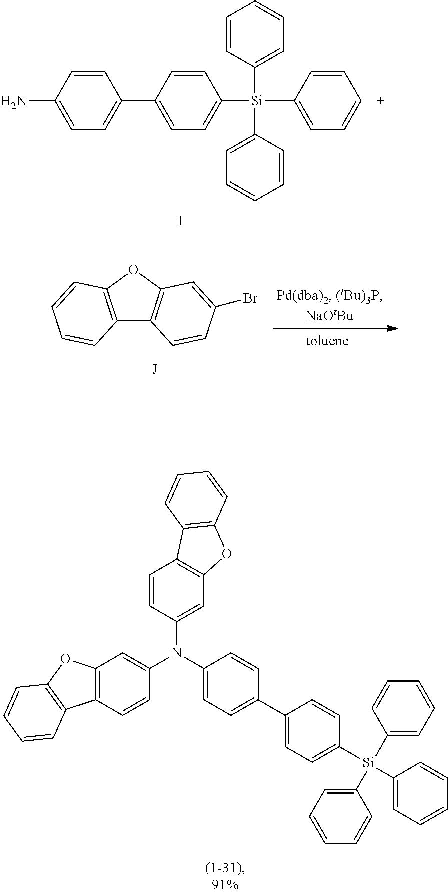

In the synthesis of Compound 1-31, 2.00 g of Compound I, 1.15 g of Compound J, 0.18 g of bis(dibenzylideneacetone)palladium(0) (Pd(dba)₂), 0.22 g of tri-tert-butylphosphine ((t-Bu)₃P) and 0.65 g of sodium tert-butoxide were added to a 100 mL three necked flask under an argon atmosphere, followed by heating and refluxing the resulting mixture in 55 mL of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 3.23 g of a target product as a white solid (Yield 91%).

The chemical shift values of the target product measured by ¹H NMR were 8.004-7.98 (m, 4H), 7.88-7.79 (m, 4H), 7.65-7.29 (m, 27H), 6.91 (d, 2H). In addition, the molecular weight of the target product measured by FAB-MS was about 760. From these results, the target product was confirmed to be Compound 1-31.

### Synthetic Example 9

### Synthesis of Compound 1-33 Represented by Formula 1-33

According to the following reaction scheme, Compound 1-33 represented by Formula 1-33 was synthesized.

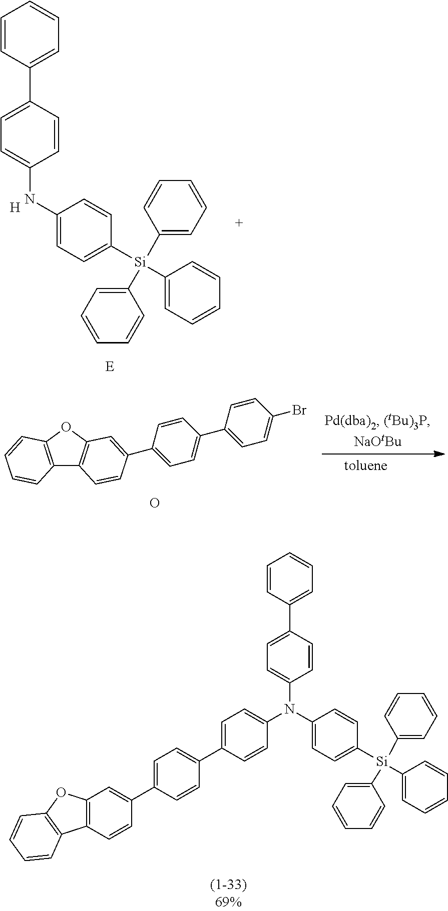

In the synthesis of Compound 1-33, 1.50 g of Compound E, 1.42 g of Compound O, 0.21 g of bis(dibenzylideneacetone)palladium(0) (Pd(dba)₂), 0.33 g of tri-tert-butylphosphine ((t-Bu)₃P) and 0.83 g of sodium tert-butoxide were added to a 100 mL three necked flask under an argon atmosphere, followed by heating and refluxing the resulting mixture in 80 mL of a toluene solvent for about 7 hours. After air cooling the obtained solution, water was added to separate an organic layer, and the solvent was distilled. The crude product thus obtained was separated using silica gel column chromatography (using a mixed solvent of dichloromethane and hexane) and recrystallized using a mixed solvent of toluene and hexane to produce 1.68 g of a target product as a white solid (Yield 69%).

The chemical shift values of the target product measured by ¹H NMR were 8.003 (d, 1H), 7.97 (d, 1H), 7.84 (d, 1H), 7.76-7.75 (m, 3H) 7.73-7.25 (m, 37H). In addition, the molecular weight of the target product measured by FAB-MS was about 822. From these results, the target product was confirmed to be Compound 1-33.

### (Manufacturing Example 1 of Organic Electroluminescent Device)

An organic electroluminescent device was manufactured by the following manufacturing method. An ITO-glass substrate, patterned and washed in advance, was surface-treated using UV-Ozone (O₃). The layer thickness of an ITO layer (used herein as the first electrode) was about 150 nm. After ozone treatment, the substrate was washed. After the washing, the substrate was inserted into a glass bell jar type (or kind) evaporator for forming an organic layer, and then HTL1 HTL2, and HTL3 hole transport materials, an emission layer, and an electron transport layer were evaporated one by one at a vacuum degree of about 10⁻⁴ to about 10⁻⁵ Pa and deposited on the substrate. Here, “HTL1”, “HTL2” and “HTL3” correspond to hole transport materials including the compounds as shown in Table 1. The layer thickness of each of the layers using HTL1, HTL2 and HTL3 hole transport materials was about 10 nm. The layer thickness of the emission layer was about 25 nm, and the layer thickness of the electron transport layer was about 25 nm. Then, the substrate was moved into a glass bell jar type (or kind) evaporator for forming a metal layer, where an electron injection layer and a material for forming a cathode (used herein as a second electrode) were evaporated at a vacuum degree of about 10⁻⁴ to about 10⁻⁵ Pa and deposited on the electron transport layer. The layer thickness of the electron injection layer was about 1.0 nm and the layer thickness of the second electrode was about 100 nm.

In Table 1, Compounds 6-1 to 6-2 are represented by the following formulae:

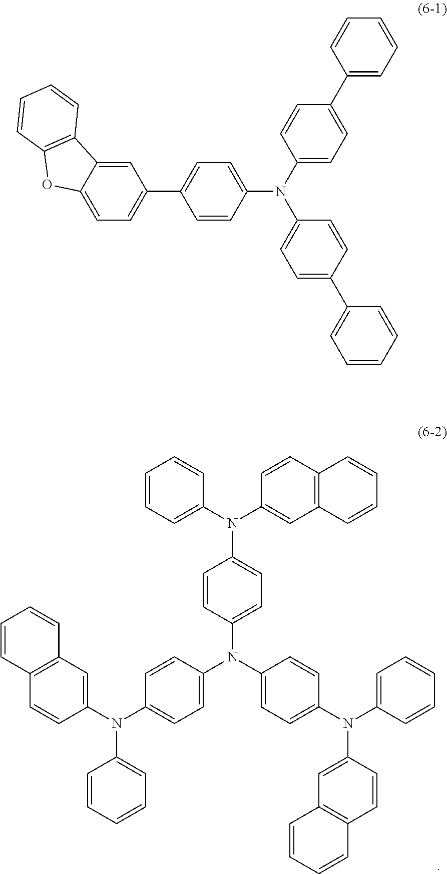 [SMILES: c1ccc(-c2ccc(N(c3ccc(-c4ccccc4)cc3)c3ccc(-c4ccc5oc6ccccc6c5c4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

In the emission layer, the host was 9,10-di(2-naphthyl)anthracene (ADN, Compound 3-2) or bis(2,2-diphenylvinyl)-1,1′-biphenyl (DPVBi, Compound 3-13), and the dopant was 2,5,8,11-tetra-t-butylperylene (TBP). The dopant was added in an amount ratio of about 3 wt % based on the amount of the host. Alq3 was used as the electron transport material, and LiF was used as the electron injection material. Al was used as the second electrode material.

TABLE 1

| | First Hole | Third Hole | Second Hole | | | | |
|---|---|---|---|---|---|---|---|
| | Transport | Transport | Transport | | | | |
| | Layer (HTL1 | Layer (HTL2 | Layer (HTL3 | | | Emission | |
| | hole transport | hole transport | hole transport | Host | Voltage | efficiency | Half Life |
| Example | material) | material) | material) | material | (V) | (cd/A) | LT50 (h) |
| Example 1 | Compound | Compound | Compound | ADN | 6.5 | 7.9 | 3,100 |
| | 4-15 | 2-3 | 1-3 | | | | |
| Example 2 | Compound | Compound | Compound | ADN | 6.4 | 7.5 | 2,400 |
| | 4-15 | 2-3 | 1-9 | | | | |
| Example 3 | Compound | Compound | Compound | ADN | 6.3 | 7.6 | 2,600 |
| | 4-15 | 2-3 | 1-17 | | | | |
| Example 4 | Compound | Compound | Compound | ADN | 6.8 | 7.7 | 3,000 |
| | 4-15 | 2-3 | 1-19 | | | | |
| Example 5 | Compound | Compound | Compound | ADN | 6.8 | 6.5 | 3,100 |
| | 4-15 | 1-3 | 2-3 | | | | |
| Example 6 | Compound | Compound | Compound | ADN | 6.9 | 5.5 | 2,000 |
| | 2-3 | 4-15 | 1-3 | | | | |
| Example 7 | Compound | Compound | Compound | ADN | 6.6 | 7.7 | 2,400 |
| | 4-15 | 2-3 | 1-25 | | | | |
| Example 8 | Compound | Compound | Compound | ADN | 6.5 | 7.9 | 2,900 |
| | 4-15 | 2-3 | 1-31 | | | | |
| Example 9 | Compound | Compound | Compound | ADN | 6.8 | 7.3 | 2,700 |
| | 4-16 | 2-3 | 1-3 | | | | |
| Example 10 | Compound | Compound | Compound | DPVBi | 6.6 | 7.3 | 2,200 |
| | 4-15 | 2-3 | 1-3 | | | | |
| Example 11 | Compound | Compound | Compound | ADN | 6.5 | 7.9 | 2,600 |
| | 4-15 | 2-3 | 1-28 | | | | |
| Example 12 | Compound | Compound | Compound | ADN | 6.5 | 7.7 | 2,700 |
| | 4-15 | 2-3 | 1-29 | | | | |
| Example 13 | Compound | Compound | Compound | ADN | 6.2 | 7.7 | 2,800 |
| | 4-15 | 2-3 | 1-33 | | | | |
| Comparative | Compound | Compound | Compound | ADN | 6.6 | 6.5 | 3,000 |
| Example 1 | 4-15 | 2-3 | 2-3 | | | | |
| Comparative | Compound | Compound | Compound | ADN | 7.5 | 5.5 | 1,900 |
| Example 2 | 4-15 | 2-3 | 6-1 | | | | |
| Comparative | Compound | Compound | Compound | ADN | 7.9 | 5.8 | 2,000 |
| Example 3 | 6-2 | 2-3 | 1-3 | | | | |
| Comparative | Compound | Compound | Compound | ADN | 7.5 | 4.8 | 1,500 |
| Example 4 | 6-2 | 2-3 | 6-1 | | | | |
| Comparative | Compound | Compound | Compound | ADN | 8.1 | 4.3 | 700 |
| Example 5 | 6-2 | 6-2 | 6-1 | | | | |

In Examples 1 to 4, HTL1, HTL2, and HTL3 were respectively included in the first hole transport layer, the third hole transport layer and the second hole transport layer. Organic electroluminescent devices of Examples 2 to 4, were manufactured in substantially the same manner as in Example 1, except that the HTL3 hole transport material was changed.

Organic electroluminescent device of Example 5 was manufactured in substantially the same manner as in Example 1, except that the stacking order of the second hole transport layer and the third hole transport layer was exchanged. That is, HTL2 hole transport material included in the third hole transport layer of Example 1 was now included in the second hole transport layer of Example 5 was positioned adjacent the emission layer. Organic electroluminescent device of Example 6 was manufactured in substantially the same manner as in Example 1 except that the stacking order of the first hole transport layer and the third hole transport layer was exchanged. Here, HTL2 hole transport material included in the third hole transport layer of Example 1 was now included in the first hole transport layer of Example 6 positioned adjacent to the first electrode. In Examples 7 and 8, organic electroluminescent devices were manufactured in substantially the same manner as in Example 1, except that the materials included in the respective second hole transport layers were changed. In Example 9, organic electroluminescent device was manufactured in substantially the same manner as in Example 1, except that the HTL1 hole transport material was changed to include a different electron accepting material. In Example 10, organic electroluminescent device was manufactured in substantially the same manner as in Example 1, except that the host material was changed. In Examples 11 to 13, organic electroluminescent devices were manufactured in substantially the same manner as in Example 1, except that the HTL3 hole transport materials included in the respective second hole transport layers were changed.

In Comparative Example 1, organic electroluminescent device was manufactured in substantially the same manner as in Example 1, except that the third and second hole transport layers of Comparative Example 1 both included the HTL2 hole transport material included in the third hole transport layer of Example 1. In Comparative Example 2, organic electroluminescent device was manufactured in substantially the same manner as in Example 1, except that the HTL3 hole transport material was Compound 6-1.

In Comparative Example 3, organic electroluminescent device was manufactured in substantially the same manner as in Example 1, except that the HTL1 hole transport material was Compound 6-2. In Comparative Example 4, organic electroluminescent device was manufactured in substantially the same manner as in Comparative Example 2, except that the HTL1 hole transport material was Compound 6-2. In Comparative Example 5, organic electroluminescent device was manufactured in substantially the same manner as in Comparative Example 4 except that the HTL2 hole transport material was Compound 6-2.

### (Evaluation of Properties of Organic Electroluminescent Device)

Driving voltage, emission efficiency, and half life of each of the organic electroluminescent devices manufactured according to Examples and Comparative Examples were measured. The measurements for the driving voltage and the emission efficiency were obtained using current density of about 10 mA/cm². The measurements for half life were obtained by measuring the time it took for the initial luminance of about 1,000 cd/m² to reduce by 50%. The measurements were taken using a 2400 series source meter from Keithley Instruments Co., Color brightness photometer CS-200 (manufactured by Konica Minolta, measurement angle of 1)°, and a PC program LabVIEW 8.2 (manufactured by National instruments in Japan) for measurements in a dark room. Evaluation results are shown in Table 1.

As illustrated by the results in Table 1, the organic electroluminescent devices according to Examples 1 to 13 exhibited better results in at least one selected from the emission efficiency and emission life (here, based on the measurements for half life) when compared to those of Comparative Examples 1 to 5. In addition, driving voltage, emission efficiency, and emission life of the organic electroluminescent device of Example 1 were improved as compared to those of the organic electroluminescent devices of Comparative Examples 1 to 5. Without being bound by any particular theory, it is believed that at least one selected from the emission efficiency and emission life of the organic electroluminescent device could be increased by providing the first hole transport layer and the second hole transport layer according to embodiments of the present invention between the first electrode and the emission layer. In addition, at least one selected from the emission efficiency and emission life of the organic electroluminescent device could be further improved by positioning the second hole transport layer according to embodiments of the present invention between the first hole transport layer and the emission layer).

Furthermore, among the organic electroluminescent devices of Examples 1 to 4, emission efficiency and emission life of Example 1 were the best. This is at least partially because the properties of the organic electroluminescent device can be improved when an amine moiety is coupled with a dibenzofuran moiety at position 3 of the dibenzofuran moiety. In some embodiments, when comparing Example 1 and Example 5, the driving voltage and the emission efficiency of Example 1 were better than those of Example 5. Accordingly, improved characteristics can be obtained when the second hole transport layer according to embodiments of the present invention is positioned adjacent to the emission layer.

In addition, driving voltage, emission efficiency, and emission life of the organic electroluminescent device of Example 1 were better than those of Example 6. Therefore, an organic electroluminescent device can exhibit improved properties when the first hole transport layer including an electron accepting material is positioned adjacent to the first electrode.

Finally, when the HTL1 hole transport material including an electron accepting material according to embodiments of the present invention was used in the first hole transport layer and the second hole transport layer according to embodiments of the present invention was positioned adjacent to the emission layer driving voltage tended to decrease and emission life tended to increase.

### (Manufacturing Example 2 of an Organic Electroluminescent Device and Evaluation of Properties Thereof)

An organic electroluminescent device having a two-layer hole transport layer structure illustrated in FIG. 2 was manufactured in substantially the same manner as in Manufacturing Example 1 except that the third hole transport layer including the HTL2 hole transport material was omitted. The evaluation of the properties of the resulting organic electroluminescent devices was conducted in substantially the same manner as described in connection with Manufacturing Example 1. The configuration of the organic electroluminescent devices according to Manufacturing Example 2 and the results of the evaluation of their properties are summarized in Table 2. As shown in Table 2, the organic electroluminescent devices according to embodiments of the present invention were found to have improved properties, even when the third hole transport layer was omitted

TABLE 2

| | First Hole | Second Hole | | | | |
|---|---|---|---|---|---|---|
| | Transport | Transport | | | | |
| | Layer (HTL1 | Layer (HTL3 | | | Emission | |
| | hole transport | hole transport | Host | Voltage | efficiency | Half Life |
| Example | material) | material) | material | (V) | (cd/A) | LT50 (h) |
| Example 14 | Compound | Compound | ADN | 6.9 | 7.6 | 3,000 |
| | 4-15 | 1-3 | | | | |
| Example 15 | Compound | Compound | ADN | 6.6 | 7.6 | 2,000 |
| | 4-15 | 1-9 | | | | |
| Example 16 | Compound | Compound | ADN | 6.3 | 7.0 | 2,500 |
| | 4-15 | 1-17 | | | | |
| Example 17 | Compound | Compound | ADN | 7.7 | 6.5 | 2,300 |
| | 4-15 | 1-19 | | | | |
| Example 18 | Compound | Compound | ADN | 7.2 | 7.7 | 1,600 |
| | 4-15 | 1-25 | | | | |
| Example 19 | Compound | Compound | ADN | 6.8 | 6.6 | 2,700 |
| | 4-15 | 1-31 | | | | |
| Example 20 | Compound | Compound | ADN | 7.4 | 7.0 | 2,700 |
| | 4-15 | 1-3 | | | | |
| Example 21 | Compound | Compound | DPVBi | 6.6 | 7.3 | 2,000 |
| | 4-15 | 1-3 | | | | |
| Example 22 | Compound | Compound | ADN | 7.5 | 6.9 | 2,500 |
| | 4-16 | 1-28 | | | | |
| Example 23 | Compound | Compound | ADN | 6.9 | 7.0 | 2,000 |
| | 4-15 | 1-29 | | | | |
| Example 24 | Compound | Compound | ADN | 7.5 | 6.5 | 2,200 |
| | 4-15 | 1-33 | | | | |
| Comparative | Compound | Compound | ADN | 6.9 | 6.1 | 2,500 |
| Example 6 | 4-15 | 2-3 | | | | |
| Comparative | Compound | Compound | ADN | 7.6 | 5.8 | 1,900 |
| Example 7 | 4-15 | 6-1 | | | | |
| Comparative | Compound | Compound | ADN | 8.6 | 5.8 | 1,800 |
| Example 8 | 6-2 | 1-3 | | | | |
| Comparative | Compound | Compound | ADN | 8.4 | 4.1 | 1,600 |
| Example 9 | 6-2 | 6-1 | | | | |
| Comparative | Compound | Compound | ADN | 7.0 | 4.2 | 800 |
| Example 10 | 1-3 | 4-15 | | | | |

As illustrated in Table 2, the organic electroluminescent devices of Examples 14 to 24 including the second hole transport layer according to embodiments of the present invention between the first hole transport layer and the emission layer exhibited improved emission efficiency and mostly improved emission life (here, based on the measurements of half life) as compared with those of the organic electroluminescent devices of Comparative Examples 6 to 10. Without being bound by any particular theory, it is believed that that the organic electroluminescent device of embodiments of the present invention can effectively perform the following functions: (1) passivating the hole transport layer from the excess electrons not consumed in the emission layer, (2) preventing or substantially blocking the diffusion of energy of an excited state (e.g., excitons) generated in the emission layer into the hole transport layer, and (3) controlling the charge balance of the entire organic electroluminescent device. Without being bound by any particular theory, it is believed that the second hole transport layer can restrain (or substantially block) the diffusion of the electron accepting material included in the first hole transport layer (adjacent to the first electrode) into the emission layer.

In some embodiments, at least one selected from the emission efficiency and emission life of the organic electroluminescent device may be further improved when the first hole transport material represented by Formula 1 includes a silyl group substituted with a substituted or unsubstituted aryl group.

In some embodiments, at least one selected from the emission efficiency and emission life of the organic electroluminescent device may be further improved when the silyl group in Formula 1 is substituted with an unsubstituted phenyl group.

In some embodiments, at least one selected from the emission efficiency and emission life of the organic electroluminescent device may be further improved when L in Formula 1 is combined (or coupled) with a dibenzofuranyl group (e.g., Ar₂ in Formula 1) at position 3 of the dibenzofuranyl group.

In some embodiments, at least one selected from the emission efficiency and emission life of the organic electroluminescent device may be further improved when the second hole transport material is represented by Formula 2.

In some embodiments, at least one selected from the emission efficiency and emission life of the organic electroluminescent device may be further improved when the electron accepting material has a LUMO level from about −9.0 to about −4.0 eV.

In some embodiments, at least one selected from the emission efficiency and emission life of the organic electroluminescent device may be further improved when the emission layer includes the luminescent material represented by Formula 3.

In some embodiments, at least one selected from the emission efficiency and emission life of the organic electroluminescent device may be further improved when the second hole transport layer is positioned between the first hole transport layer and the emission layer.

In some embodiments, at least one selected from the emission efficiency and emission life of the organic electroluminescent device may be further improved when the second hole transport layer is adjacent to the emission layer.

In some embodiments, at least one selected from the emission efficiency and emission life of the organic electroluminescent device may be further improved when the first hole transport layer is adjacent to the first electrode (e.g., anode).

In some embodiments, at least one selected from the emission efficiency and emission life of the organic electroluminescent device may be further improved when the third hole transport layer is positioned between the first hole transport layer and the second hole transport layer.

While certain embodiments of the present invention have been described, it is to be understood that the present invention is not limited to the disclosed embodiments, but, on the contrary, is intended to cover various modifications, enhancements, and equivalent arrangements included within the spirit and scope of the appended claims and equivalents thereof. Thus, to the maximum extent allowed by law, the scope of the present invention is to be determined by the broadest permissible interpretation of the following claims and their equivalents, and shall not be restricted or limited by the foregoing detailed description.

Expressions such as “at least one selected from” and “one selected from,” when preceding a list of elements, modify the entire list of elements and do not modify the individual elements of the list. Further, the use of “may” when describing embodiments of the present invention refers to “one or more embodiments of the present invention.”

In addition, as used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112a, and 35 U.S.C. §132(a).

What is claimed is:

1. An organic electroluminescent device, comprising:
an anode;
an emission layer;
a first hole transport layer between the anode and the emission layer, the first hole transport layer comprising an electron accepting material; and
a second hole transport layer between the anode and the emission layer, the second hole transport layer comprising a first hole transport material represented by Formula 1: 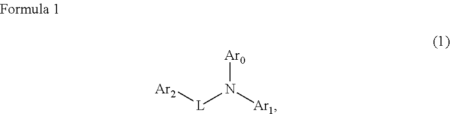
wherein, in Formula 1, Ar₀ to Ar₁ are each independently a substituted or unsubstituted aryl group or a substituted or unsubstituted heteroaryl group,
at least one of Ar₀ and Ar₁ is substituted with a substituted or unsubstituted silyl group,
Ar₂ is a substituted or unsubstituted dibenzofuranyl group, and
L is a bond, a substituted or unsubstituted arylene group, or a substituted or unsubstituted heteroarylene group.

2. The organic electroluminescent device of claim 1, wherein the substituted silyl group is a silyl group substituted with a substituted or unsubstituted aryl group.

3. The organic electroluminescent device of claim 2, wherein the substituted silyl group is a silyl group substituted with an unsubstituted phenyl group.

4. The organic electroluminescent device of claim 1, wherein L is coupled to Ar₂ at position 3 of the dibenzofuranyl group.

5. The organic electroluminescent device of claim 1, wherein the electron accepting material has a lowest unoccupied molecular orbital (LUMO) level from about −9.0 eV to about −4.0 eV.

6. The organic electroluminescent device of claim 1, wherein the emission layer comprises a luminescent material represented by Formula 3: 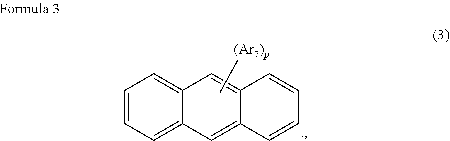
wherein, in Formula 3,
Ar₇ is selected from hydrogen, deuterium, a substituted or unsubstituted alkyl group having 1 to 50 carbon atoms, a substituted or unsubstituted cycloalkyl group having 3 to 50 carbon atoms as ring-forming atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms as ring-forming atoms, a substituted or unsubstituted arylthio group having 6 to 50 carbon atoms as ring-forming atoms, a substituted or unsubstituted alkoxycarbonyl group having 2 to 50 carbon atoms, a substituted or unsubstituted aryl group having 6 to 50 carbon atoms as ring-forming atoms, a substituted or unsubstituted heteroaryl group having 5 to 50 carbon atoms as ring-forming atoms, a substituted or unsubstituted silyl group, a carboxyl group, halogen, a cyano group, a nitro group, and a hydroxyl group, and
p is an integer from 1 to 10.

7. The organic electroluminescent device of claim 1, wherein the second hole transport layer is between the first hole transport layer and the emission layer.

8. The organic electroluminescent device of claim 7, wherein the second hole transport layer is adjacent to the emission layer.

9. The organic electroluminescent device of claim 1, wherein the first hole transport layer is adjacent to the anode.

10. The organic electroluminescent device of claim 1, further comprising a third hole transport layer between the first hole transport layer and the second hole transport layer, the third hole transport layer comprising at least one selected from the first hole transport material and a second hole transport material.

11. The organic electroluminescent device of claim 10, wherein the second hole transport material is represented by Formula 2: 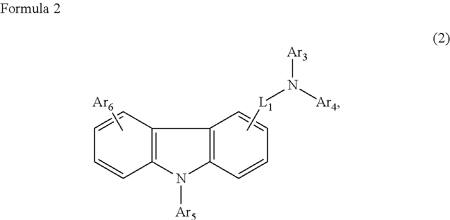
wherein, in Formula 2,
Ar₃ to Ar₅ are each independently a substituted or unsubstituted aryl group or a substituted or unsubstituted heteroaryl group,
Ar₆ is a substituted or unsubstituted aryl group, a substituted or unsubstituted heteroaryl group, a carbazolyl group, or an alkyl group, and
L₁ is a bond, a substituted or unsubstituted arylene group, or a substituted or unsubstituted heteroarylene group.

12. The organic electroluminescent device of claim 1, wherein the first hole transport material comprises at least one compound represented by any of Formulae 1-1 to 1-34:

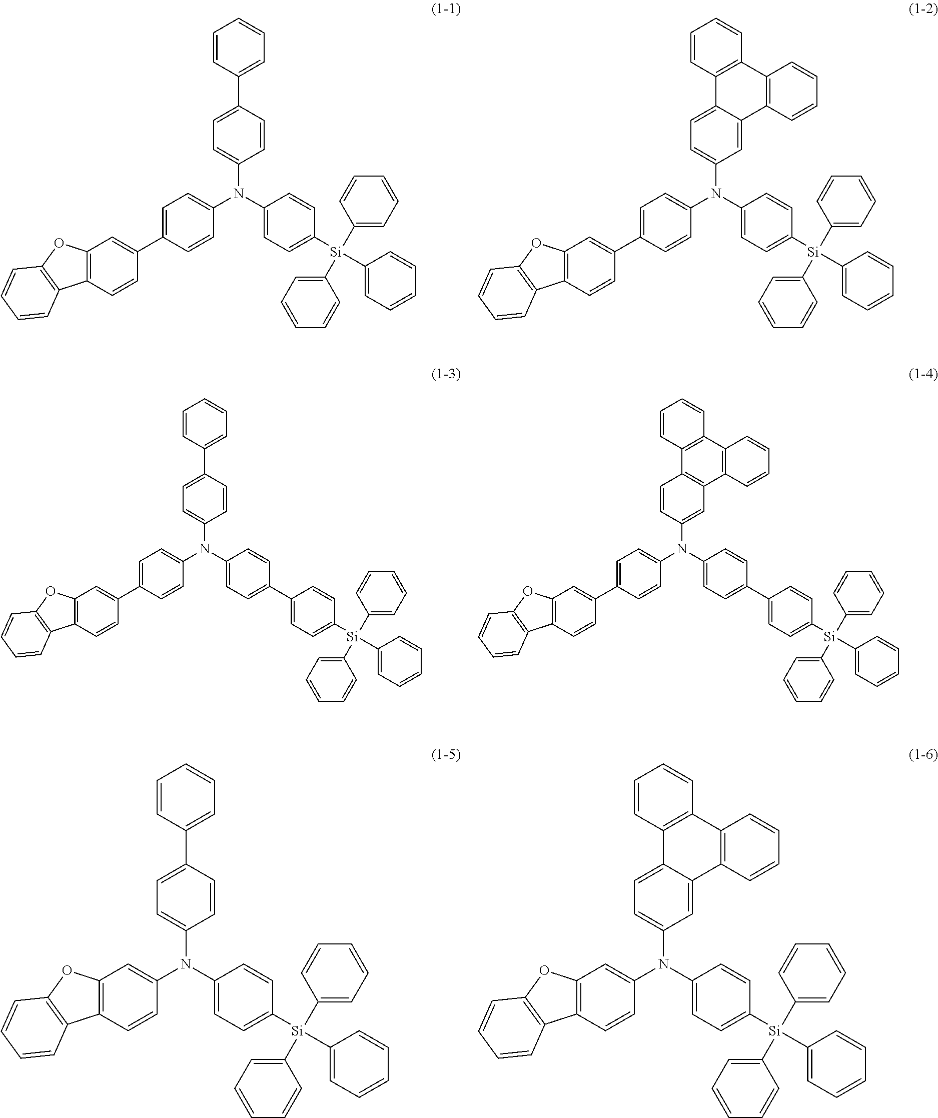

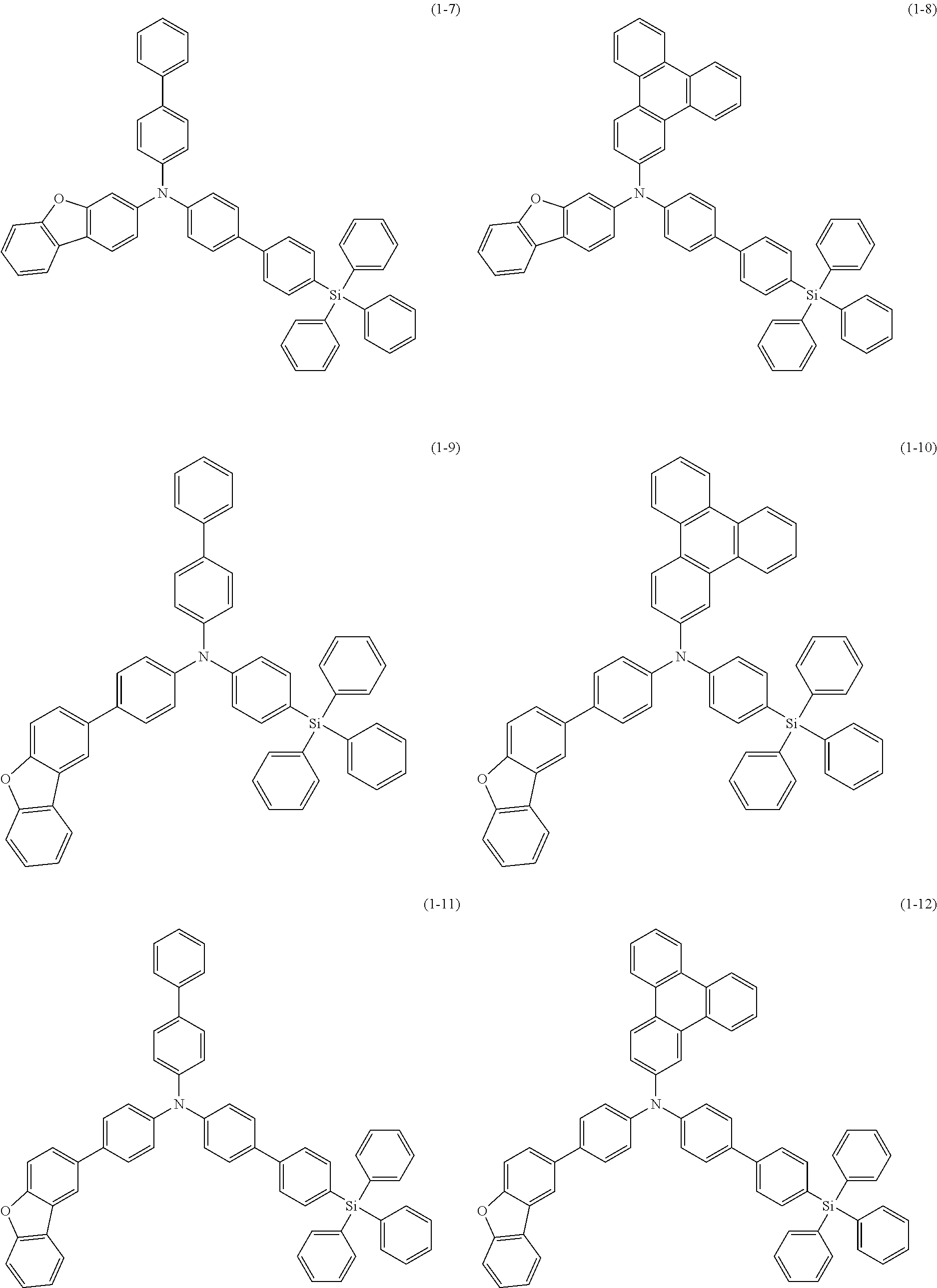

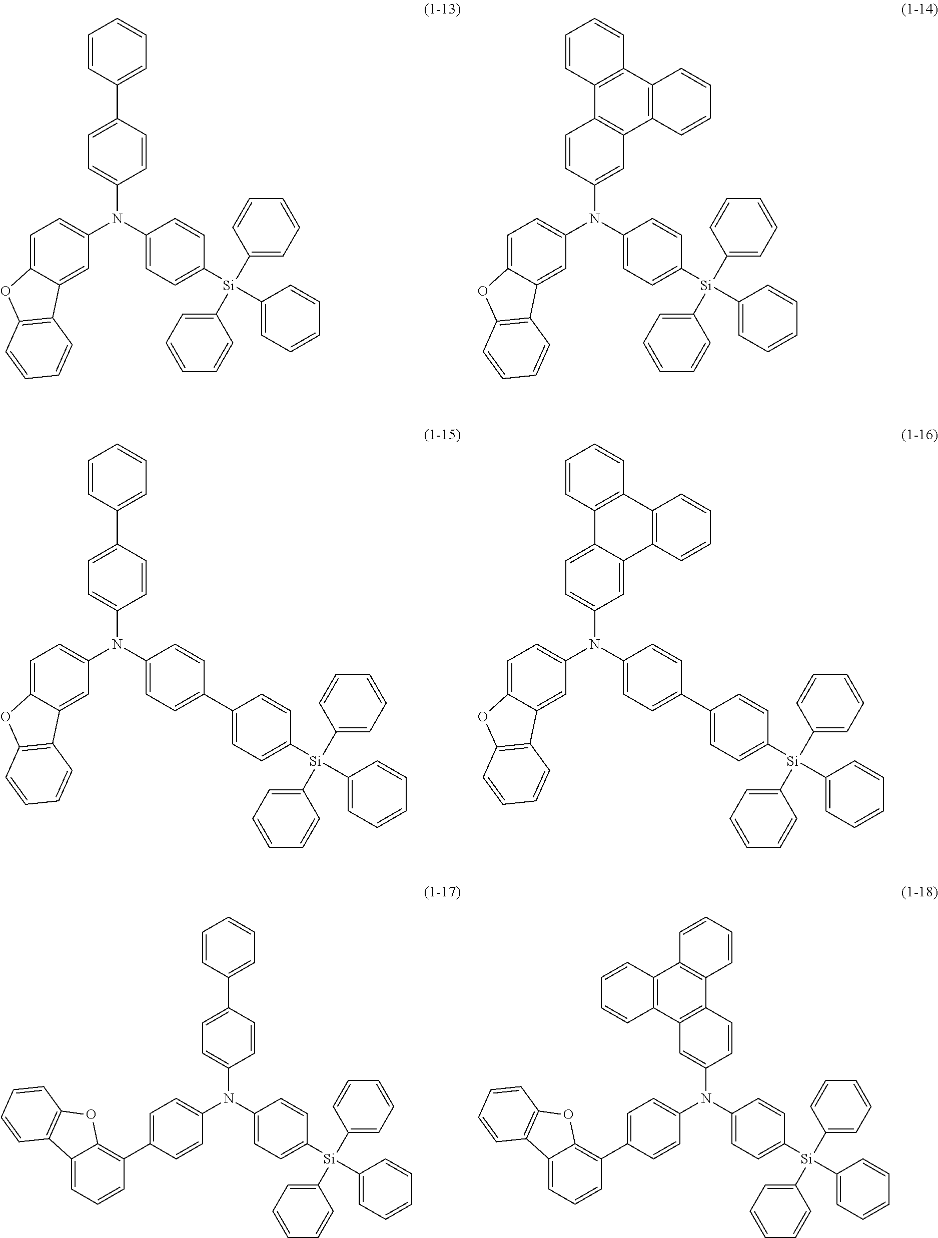

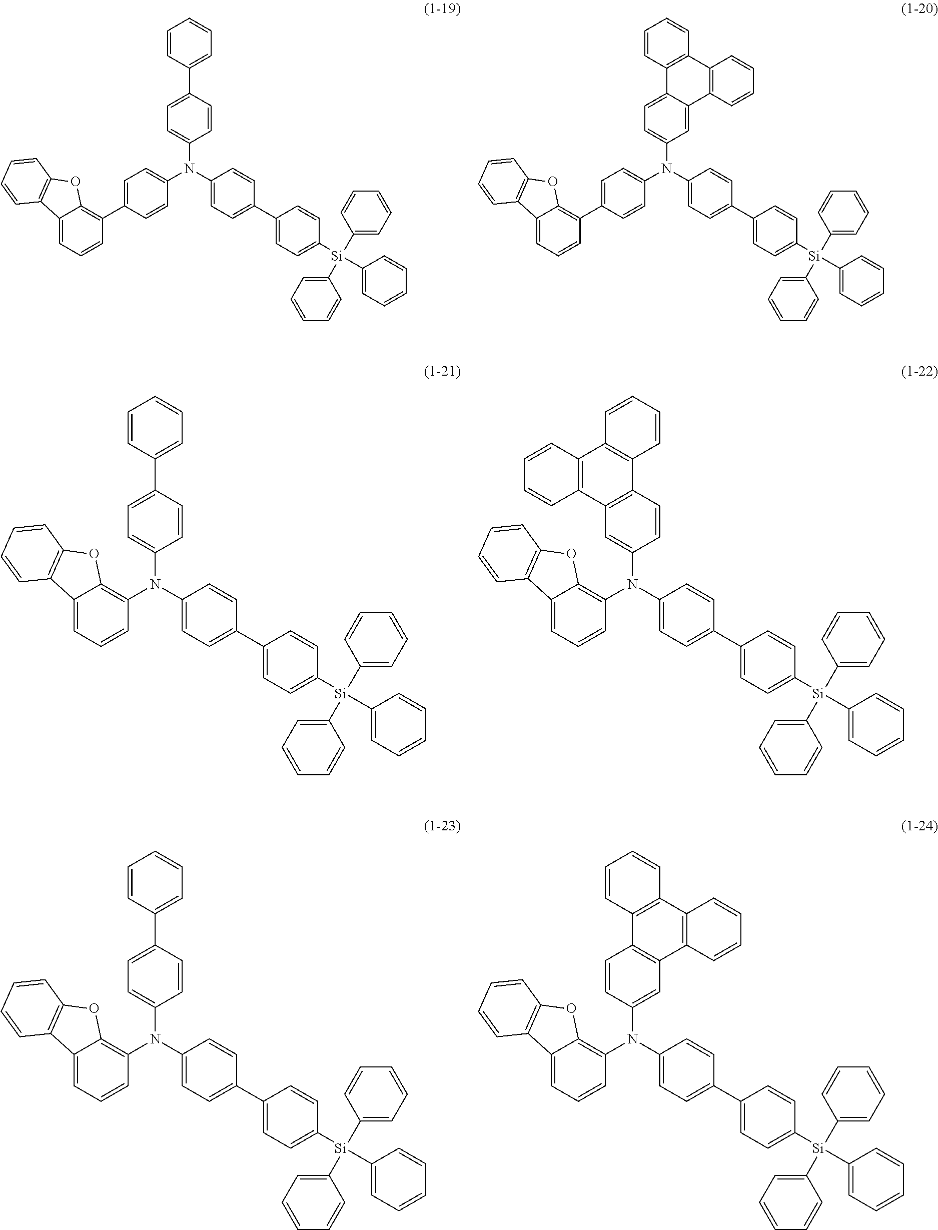

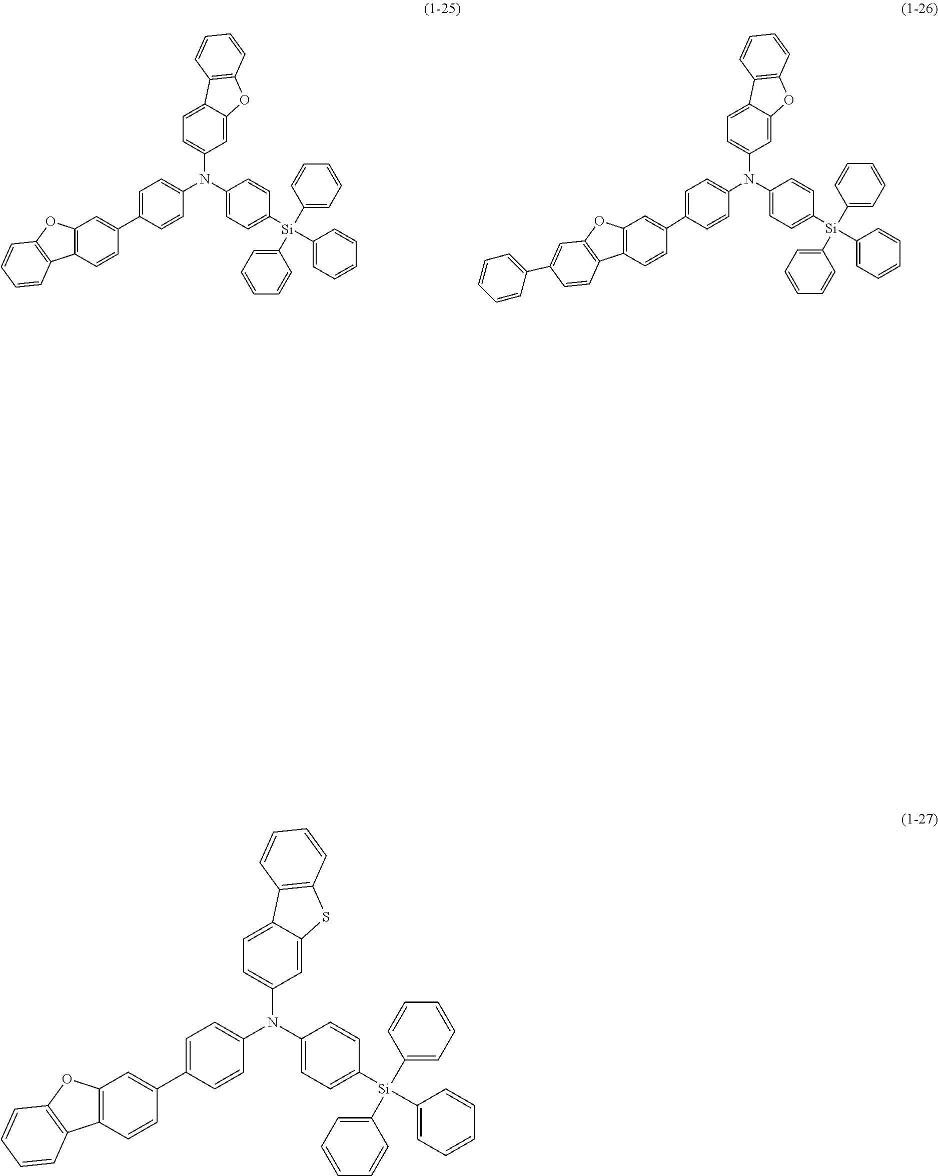 [SMILES: c1ccc([Si](c2ccccc2)(c2ccccc2)c2ccc(N(c3ccc(-c4ccc5c(c4)oc4ccccc45)cc3)c3ccc4c(c3)oc3ccccc34)cc2)cc1 ; c1ccc(-c2ccc3c(c2)oc2cc(-c4ccc(N(c5ccc([Si](c6ccccc6)(c6ccccc6)c6ccccc6)cc5)c5ccc6c(c5)oc5ccccc56)cc4)ccc23)cc1 ; c1ccc([Si](c2ccccc2)(c2ccccc2)c2ccc(N(c3ccc(-c4ccc5c(c4)oc4ccccc45)cc3)c3ccc4c(c3)sc3ccccc34)cc2)cc1]

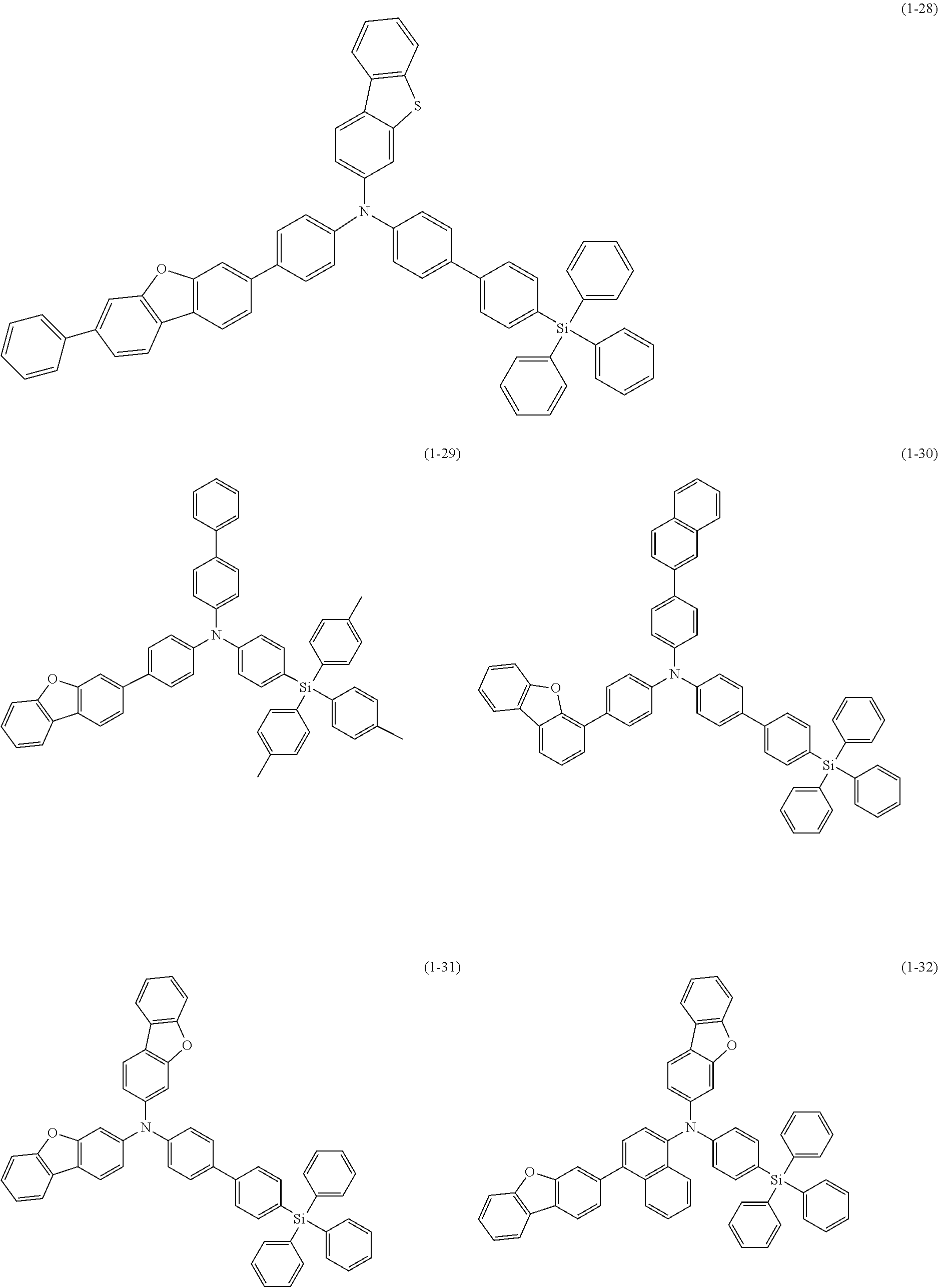

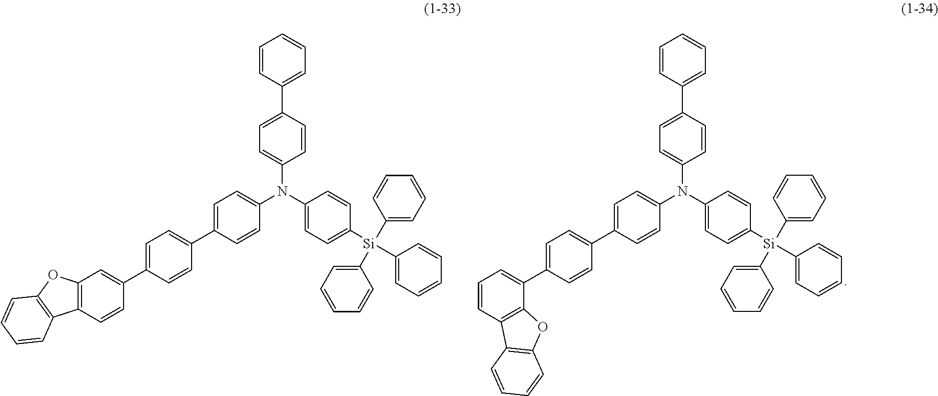 [SMILES: c1ccc(-c2ccc(N(c3ccc(-c4ccc(-c5ccc6c(c5)oc5ccccc56)cc4)cc3)c3ccc([Si](c4ccccc4)(c4ccccc4)c4ccccc4)cc3)cc2)cc1 ; c1ccc(-c2ccc(N(c3ccc(-c4ccc(-c5cccc6c5oc5ccccc56)cc4)cc3)c3ccc([Si](c4ccccc4)(c4ccccc4)c4ccccc4)cc3)cc2)cc1]

13. The organic electroluminescent device of claim 1, wherein the second hole transport material comprises at least one compound represented by any of Formulae 2-1 to 2-16:

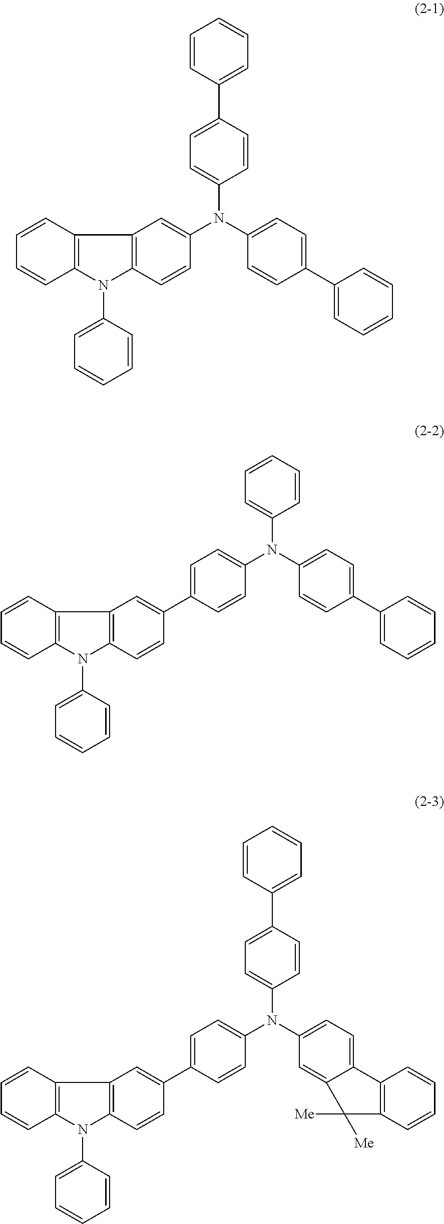 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

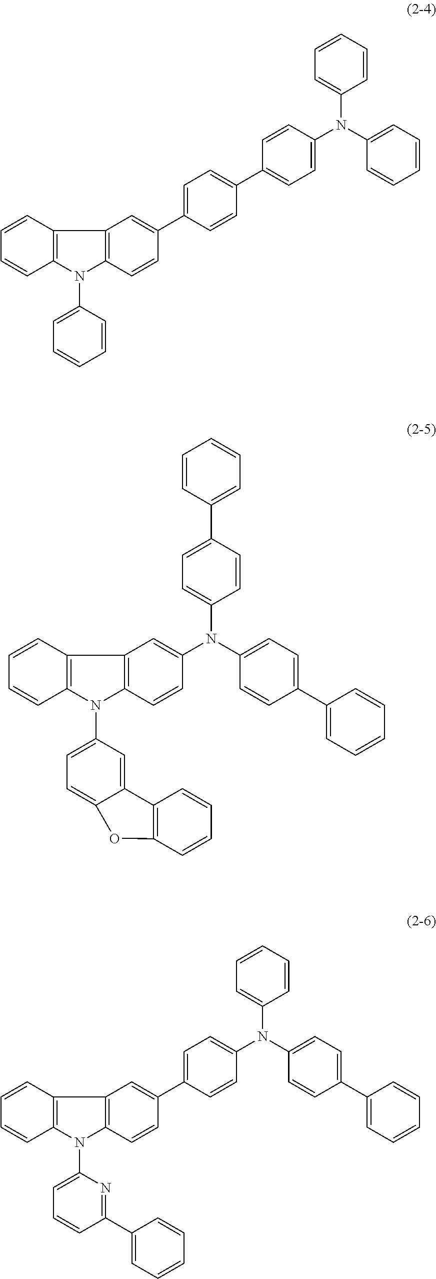 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

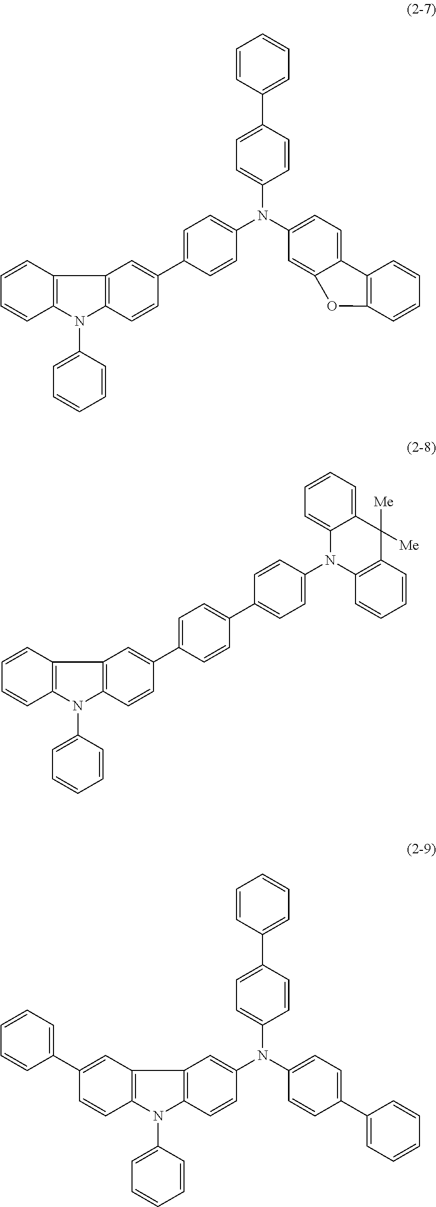 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

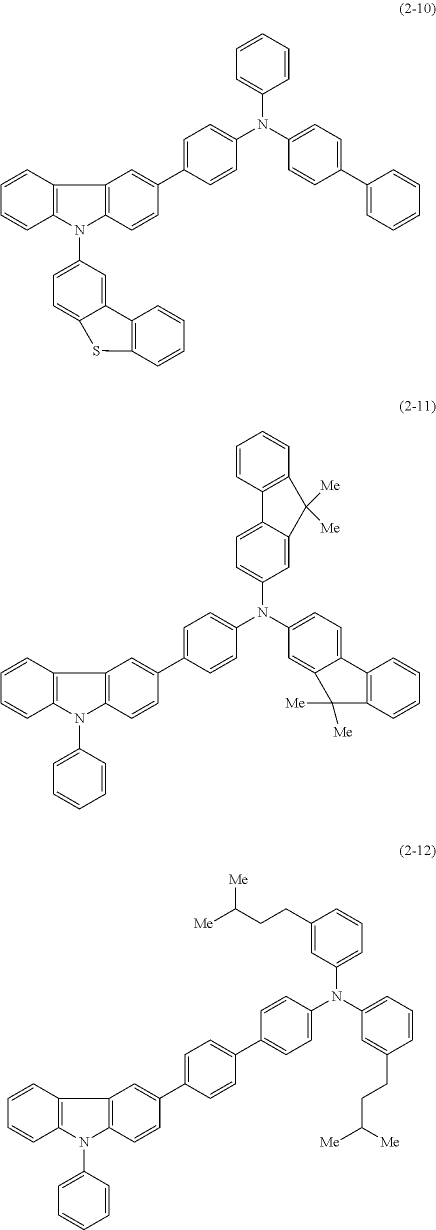 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

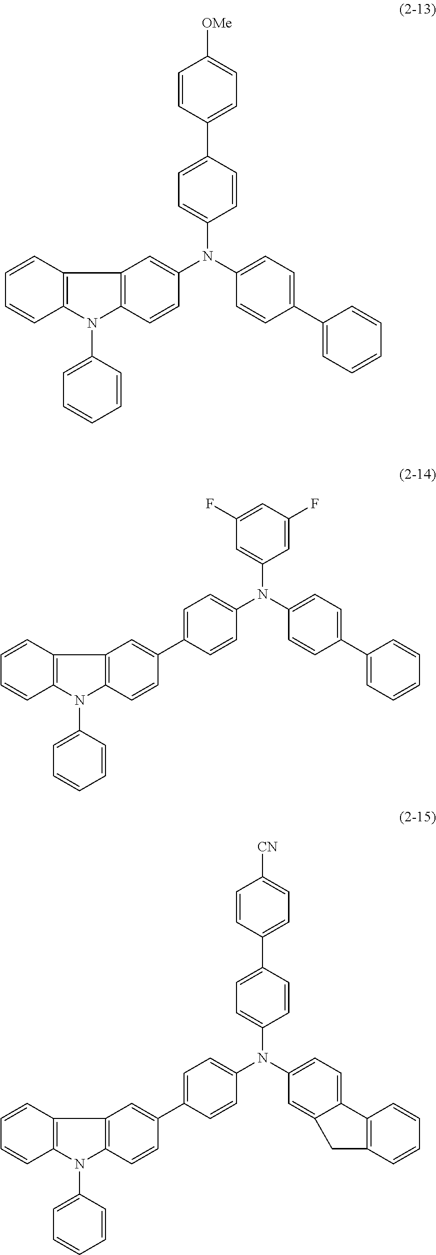 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

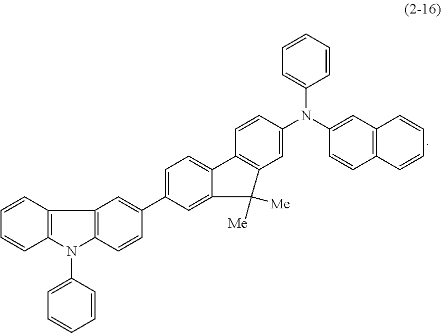 [SMILES: CC1(C)c2cc(-c3ccc4c(c3)c3ccccc3n4-c3ccccc3)ccc2-c2ccc(N(c3ccccc3)c3ccc4ccccc4c3)cc21]

14. The organic electroluminescent device of claim 1, wherein the emission layer comprises at least one compound represented by any of Formulae 3-1 to 3-12: 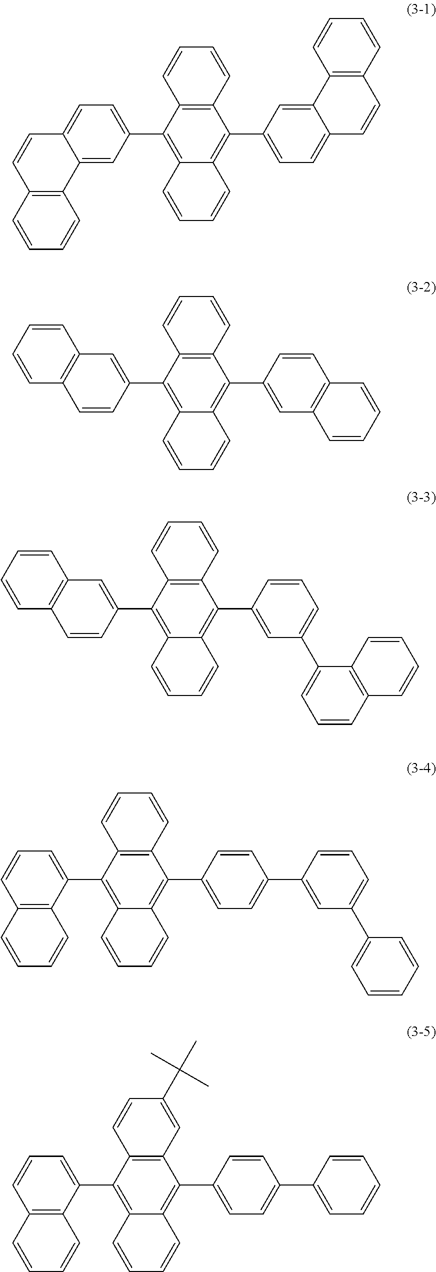 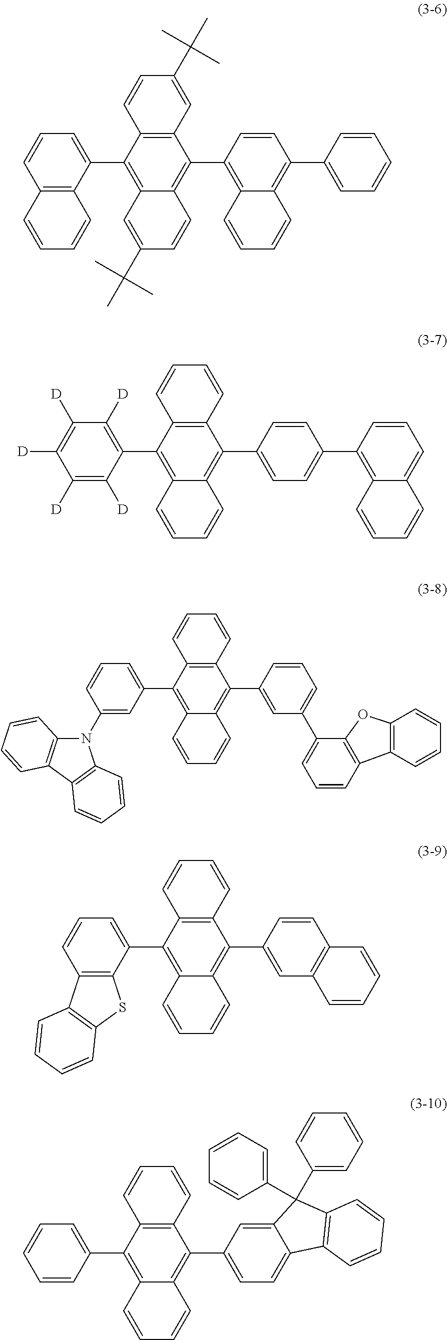 [chemical structure]
